(19) United States
(12) Patent Application Publication
(10) Pub. No.: US 2026/0370177 A1
(43) Pub. Date: Nov. 19, 2026

(54) PHOTOVOLTAIC PANEL SYSTEM HAVING W-SHAPED THREE-DIMENSIONAL PHOTOVOLTAIC PANEL ELEMENTS, AND METHOD OF MANAGING ELECTRICITY IN SAME

(71) Applicant: FIDUCIE DES BRAVES 2021, Québec (CA)

(72) Inventor: Louis MASSICOTTE, Québec (CA)

(21) Appl. No.: 19/730,929

(22) Filed: Jul. 3, 2026

Related U.S. Application Data
(63) Continuation of application No. PCT/CA2026/050148, filed on Jan. 30, 2026.
(60) Provisional application No. 63/752,094, filed on Jan. 31, 2025.
(60) Provisional application No. 63/788,245, filed on Apr. 14, 2025.
(60) Provisional application No. 63/918,897, filed on Nov. 17, 2025.

(51) Int. Cl. H02S 20/23; H02S 40/34

(52) U.S. Cl. CPC H02S 20/23; H02S 40/34

(57) ABSTRACT

There is described a photovoltaic (PV) panel system. The PV panel system generally having: PV elements having a length extending along a longitudinal orientation, the PV elements spaced relative to one another along a transverse orientation generally normal to the longitudinal orientation, the PV elements inclined about a corresponding length thereof, transverse widths of the PV elements forming alternating positive and negative non-null angles relative to the transverse orientation, the PV elements including a first set of PV elements facing a first orientation, and a second set of PV elements facing a second orientation different from the first orientation; a first electricity management device electrically connected to the first set of PV elements; and a second electricity management device electrically connected to the second set of PV elements and independent from the first set of PV elements.

### FIELD

The improvements generally relate to the field of photovoltaics (PV), and more specifically relate to building-integrated photovoltaic (BIPV) systems and panels.

### BACKGROUND

PV or BIPV panels are generally mountable or made integral to existing or new residential or commercial buildings to generate solar electricity. According to Grand View Research's report on the U.S. BIPV market, the global BIPV market size is valued at USD 19.82 billion in 2022 and is expected to exhibit a compound annual growth rate of 21.0% until 2030. This report also affirms that rapid expansion of the solar photovoltaic installation capacities of different countries, coupled with increasing demand for renewable energy sources, is expected to drive the growth of solar panel market across the world. In addition, the societal desire to reduce greenhouse gas (GHG) emissions, the increased awareness for energy security and self-sufficiency and favorable government legislations are also expected to promote the growth of the market in the coming years. Although the existing BIPV systems and panels are satisfactory to a certain degree, there remains room for improvement, especially in enhancing the efficiency per unit of surface area of the existing BIPV products.

### SUMMARY

Unlike traditional photovoltaic panels which are generally flat and installed on flat surfaces, the photovoltaic (PV) panels and systems disclosed herein can exploit a W-shaped three-dimensional structure to capture sunlight more efficiently. More specifically, there is presented a PV panel having a number of PV elements each having a length extending along a longitudinal orientation. The PV elements are spaced relative to one another along a transverse orientation which is generally normal to the longitudinal orientation. It is intended that the PV elements are each inclined about a corresponding length thereof, and by doing so transverse widths of the PV elements form alternating positive and negative non-null angles relative to the transverse orientation. The PV elements thus form a non-planar surface profile having the transverse widths zigzagging across the transverse orientation to collectively form the W-shaped three-dimensional discussed above. Indeed, it was found that the PV panels and systems disclosed herein can capture sunlight at a larger set of angles, enabling better absorption throughout the day. This is achievable even when the sun is low on the horizon. Shade reduction advantages can also be harnessed in some circumstances. For instance, thanks to the W-shaped three-dimensional structure, the PV panels and systems disclosed herein can minimize the negative effects of partial shading, which can reduce the efficiency of traditional panels. Finally, the PV panels and systems disclosed herein benefit from an increased active surface area, thereby offering greater surface area per unit of floor space in turn increasing the total amount of energy which can be produced. In accordance with preliminary simulations, it was experimentally confirmed that the PV panels and systems disclosed herein can produce, for a similar surface area, more electricity than a conventional flat PV panel currently available on the market.

In accordance with a first aspect of the present disclosure, there is provided a photovoltaic (PV) panel comprising: a plurality of PV elements having a length extending along a longitudinal orientation, the plurality of PV elements spaced relative to one another along a transverse orientation generally normal to the longitudinal orientation, the plurality of PV elements inclined about a corresponding length thereof, transverse widths of the plurality of PV elements forming alternating positive and negative non-null angles relative to the transverse orientation, the plurality of PV elements forming a non-planar surface profile.

In accordance with a second aspect of the present disclosure, there is provided an infrastructure comprising: an infrastructure portion positioned relative to a ground level and having a photovoltaic (PV) panel, the PV panel including a plurality of PV elements having a length extending along a longitudinal orientation, the plurality of PV elements spaced relative to one another along a transverse orientation generally normal to the longitudinal orientation, the plurality of PV elements inclined about a corresponding length thereof, transverse widths of the plurality of PV elements forming alternating positive and negative non-null angles relative to the transverse orientation, the plurality of PV elements forming a non-planar surface profile.

In another aspect, the PV elements may not necessarily be coupled or sealed to one another, as they can be secured on a support surface having the W-shape structure. In this aspect, there is presented an amplifying structure configured for integration with PV elements to form a PV panel assembly. The amplifying structure generally has a frame having a plurality of wall portions, each wall portion extending along a longitudinal orientation and spaced from adjacent wall portions along a transverse orientation generally orthogonal thereto. Each wall portion is inclined about its longitudinal extent such that the transverse widths of the wall portions collectively define alternating positive and negative non-null angles relative to the transverse orientation. In this manner, the wall portions form a repeating sequence of concave crests and convex crests extending longitudinally between the wall portions. These inclined wall portions form the foundation of the W-shape seats. The wall portions are configured to receive and securely support a corresponding plurality of PV elements therealong, such that, when assembled, the amplifying structure imparts a non-planar surface topology to the PV panel assembly, thereby enhancing optical capture performance through controlled geometric orientation.

In accordance with a third aspect of the present disclosure, there is provided an amplifying structure for a photovoltaic (PV) panel assembly, the amplifying structure comprising: a frame having a plurality of wall portions each having a length extending along a longitudinal orientation, the plurality of wall portions spaced relative to one another along a transverse orientation generally normal to the longitudinal orientation, the plurality of wall portions inclined about a corresponding length thereof, transverse widths of the plurality of wall portions forming alternating positive and negative non-null angles relative to the transverse orientation, thereby forming a series of concave crests interspersed with a series of convex crests each extending along the longitudinal orientation between the wall portions, the plurality of wall portions adapted to receiving a corresponding plurality of PV elements therealong to form the PV panel assembly.

In accordance with a fourth aspect of the present disclosure, there is provided a photovoltaic (PV) panel assembly comprising: a frame having a plurality of wall portions each having a length extending along a longitudinal orientation, the plurality of wall portions spaced relative to one another along a transverse orientation generally normal to the longitudinal orientation, the plurality of wall portions inclined about a corresponding length thereof, transverse widths of the plurality of wall portions forming alternating positive and negative non-null angles relative to the transverse orientation, thereby forming a series of concave crests interspersed with a series of convex crests each extending along the longitudinal orientation between the wall portions; and a plurality of PV elements received on the wall portions of the frame.

In accordance with a fifth aspect of the present disclosure, there is provided a kit of parts for assembling a PV panel assembly, the kit of parts comprising: a frame having a plurality of wall portions each having a length extending along a longitudinal orientation, the plurality of wall portions spaced relative to one another along a transverse orientation generally normal to the longitudinal orientation, the plurality of wall portions inclined about a corresponding length thereof, transverse widths of the plurality of wall portions forming alternating positive and negative non-null angles relative to the transverse orientation, thereby forming a series of concave crests interspersed with a series of convex crests each extending along the longitudinal orientation between the wall portions; a plurality of PV elements; and instructions for assembling the plurality of PV elements to corresponding ones of the plurality of wall portions to form the PV panel assembly.

In yet another aspect of the present disclosure, it was found that the PV panel and PV panel assembly presented herein may need an electrical configuration which differs from conventional electricity management modules. Accordingly, there is presented a photovoltaic (PV) panel system incorporating both a geometrically optimized PV assembly and an electrically independent dual-channel power management architecture. The PV panel system generally has a frame supporting a plurality of PV elements, each PV element extending along a longitudinal orientation and spaced from adjacent PV elements along a transverse orientation generally orthogonal thereto. The PV elements are individually inclined about their longitudinal extent such that their transverse widths collectively form alternating positive and negative non-null angles relative to the transverse orientation, thereby establishing distinct sets of PV elements oriented toward different directional exposures. The inclined PV elements can be inclined thanks to a coupling or sealing of the PV elements to one another, in accordance with the first aspect presented above, or be seated on an amplifying structure in accordance with the fourth aspect presented above. In any event, the plurality of PV elements thus includes a first set of PV elements facing a first orientation and a second set of PV elements facing a second, different orientation. The PV elements of the first set may correspond to those inclined at the positive non-null angle whereas the PV elements of the second set may correspond to those inclined at the negative non-null angle. An electricity management module is provided and comprises a first electricity management device electrically connected to the first set of PV elements, and a second electricity management device electrically connected to the second set of PV elements. The two electricity management devices operate independently of one another. As such, each electricity management device is configured to draw and condition electrical energy generated by its corresponding set of PV elements, thereby enabling orientation-specific energy harvesting, improved power extraction, and enhanced operational robustness under varying illumination conditions.

In accordance with a sixth aspect of the present disclosure, there is provided a photovoltaic (PV) panel system comprising: a frame; a plurality of PV elements mounted to the frame, the plurality of PV elements having a length extending along a longitudinal orientation, the plurality of PV elements spaced relative to one another along a transverse orientation generally normal to the longitudinal orientation, the plurality of PV elements inclined about a corresponding length thereof, transverse widths of the plurality of PV elements forming alternating positive and negative non-null angles relative to the transverse orientation, the plurality of PV elements including a first set of PV elements facing a first orientation, and a second set of PV elements facing a second orientation different from the first orientation; an electricity management module having: a first electricity management device electrically connected to the first set of PV elements; and a second electricity management device electrically connected to the second set of PV elements and independent from the first set of PV elements; wherein the first electricity management device and the second electricity management device each draws electricity generated by the first set of PV elements and the second set of PV elements, respectively.

Further in accordance with the sixth aspect of the present disclosure, the PV elements of the first set are connected to one another in series, the PV elements of the second set being connected to one another in series.

Still further in accordance with the sixth aspect of the present disclosure, the PV elements are connected to the electricity management module using dedicated conductors.

Still further in accordance with the sixth aspect of the present disclosure, the frame has a plurality of wall portions each receiving a corresponding PV element, the wall portions having an access recess through which the dedicated conductors pass.

Still further in accordance with the sixth aspect of the present disclosure, the electricity management module has at least a third electricity management device independent from the first electricity management device and the second electricity management device, the third electricity management device electrically connected to a given set of the PV elements.

Still further in accordance with the sixth aspect of the present disclosure, the electricity management module is configured for activating or deactivating either one or both the first electricity management device and the second electricity management device depending on based on one or more instantaneous sensor readings.

Still further in accordance with the sixth aspect of the present disclosure, the PV elements form a non-planar surface profile having a transverse cross-section defining a W-shape.

Still further in accordance with the sixth aspect of the present disclosure, proximate longitudinal edges of any two adjacent ones of the plurality of PV elements are abutted to one another, abutting ones of the plurality of PV elements forming a succession of concave crests and convex crests each extending along the longitudinal orientation.

Still further in accordance with the sixth aspect of the present disclosure, the PV panel system further comprising first reflective surfaces disposed along at least some of the concave crests.

Still further in accordance with the sixth aspect of the present disclosure, the first reflective surfaces have a concave shape snugly received along the at least some of the concave crests.

Still further in accordance with the sixth aspect of the present disclosure, the first reflective surfaces have a convex shape protruding from corresponding ones of the at least some of the concave crests.

Still further in accordance with the sixth aspect of the present disclosure, the PV panel system further comprising second reflective surfaces disposed along at least some of the convex crests.

Still further in accordance with the sixth aspect of the present disclosure, the second reflective surfaces protrude inwardly from corresponding ones of the convex crests.

Still further in accordance with the sixth aspect of the present disclosure, the positive non-null angles range between 30 and 50 degrees, and the negative non-null angles range between −30 and −50 degrees.

Still further in accordance with the sixth aspect of the present disclosure, the PV elements are flat PV elements.

In accordance with a seventh aspect of the present disclosure, there is provided a method of managing electricity in a photovoltaic (PV) panel system comprising: using a first electricity management device electrically connected to a first set of PV elements, the PV elements of the first set facing a first orientation, and a second electricity management device electrically connected to a second set of PV elements, the PV elements of the second set facing a second orientation different from the first orientation, drawing electricity from the first set of PV elements independently from drawing electricity from the second set of PV elements.

In accordance with an eighth aspect of the present disclosure, there is provided a bifacial panel comprising one or more PV panel or PV panel assembly as described above.

All technical implementation details and advantages described with respect to a particular aspect of the present invention are self-evidently mutatis mutandis applicable for all other aspects of the present invention.

Many further features and combinations thereof concerning the present improvements will appear to those skilled in the art following a reading of the instant disclosure.

### DESCRIPTION OF THE FIGURES

In the figures,

FIG. 1 is an oblique view of an example of an infrastructure having a number of photovoltaic (PV) panels integrated to different infrastructure portions of a building, in accordance with one or more embodiments;

FIG. 1A is a side elevation view of a given PV panel of the infrastructure of FIG. 1, taken along viewpoint 1A-1A of FIG. 1, in accordance with one or more embodiments;

FIG. 1B is a top plan view of a given PV panel of the infrastructure of FIG. 1, taken along viewpoint 1B-1B of FIG. 1, in accordance with one or more embodiments;

FIG. 1C is an enlarged view of inset 1C of FIG. 1B, in accordance with one or more embodiments;

FIG. 2 is an exploded view of the given PV panel of FIG. 1A during its assembly, in accordance with one or more embodiments;

FIG. 3A is a top plan view of an example of a PV panel forming obtuse angles between the PV elements, in accordance with one or more embodiments;

FIG. 3B is a top plan view of an example of a PV panel forming acute angles between the PV elements, in accordance with one or more embodiments;

FIGS. 3C and 3D are top plan views of exemplary PV panels having curved PV elements forming concave and convex undulated patters, in accordance with one or more embodiments;

FIG. 4 is a side elevation view of an example of a conventional PV panel shown in relation to different sun positions, in accordance with one or more embodiments;

FIG. 5 is a side elevation view of an example of a PV panel having PV elements forming a zigzag pattern having acute angles shown in relation to different sun positions, in accordance with one or more embodiments;

FIG. 6 is a side elevation view of an example of a PV panel having PV elements forming a zigzag pattern having right angles shown in relation to different sun positions, in accordance with one or more embodiments;

FIG. 7 is a schematic view of an example of a PV panel incorporating a reflective chamber, in accordance with one or more embodiments;

FIG. 8 is a schematic view of an example of a PV panel system including a PV panel and a controller, in accordance with one or more embodiments;

FIG. 8A is a schematic view of another example of a PV panel system including a PV pane and a controller having two electricity management devices, in accordance with one or more embodiments;

FIG. 9 is a schematic view of an example of a computing device of a controller of a PV panel system of FIG. 9, in accordance with one or more embodiments;

FIG. 10A is a top plan view of an example of a bifacial panel having two PV panels having a W-shaped geometry facing each other, in accordance with one or more embodiments;

FIG. 10B is an oblique view of the bifacial panel of FIG. 10A, in accordance with one or more embodiments;

FIG. 10C is an oblique view of the bifacial panel of FIG. 10A, shown with a base panel reflecting incident light towards the bifacial panel, in accordance with one or more embodiments;

FIG. 11A is a schematic view of incident light reflecting on a corrugated surface at the nanometric scale, in accordance with one or more embodiments;

FIG. 11B is a graph showing irradiance as a function of wavelength for different types of materials, overlaid with a solar light spectrum (in solid line), in accordance with one or more embodiments;

FIG. 12A is a top plan view of another example of a PV panel having reflective surfaces disposed along concave and convex crests of the PV panel, in accordance with one or more embodiments;

FIG. 12B is an oblique view of the PV panel of FIG. 12A, shown without the reflective surfaces disposed at the convex crests, in accordance with one or more embodiments;

FIG. 12C is a graph showing instantaneous power as a function of time for the PV panel of FIG. 12B, in accordance with one or more embodiments;

FIG. 13A is an oblique view of an amplifying structure for a PV panel assembly, in accordance with one or more embodiments;

FIG. 13B is a top plan view of the amplifying structure of FIG. 13A, in accordance with one or more embodiments;

FIG. 13C is a graph showing instantaneous power as a function of time for a PV panel assembled from the amplifying structure of FIG. 13A and eight PV elements, in accordance with one or more embodiments;

FIG. 13D is a histogram showing cumulated power for three different PV panels including a PV panel having a series of six PV elements arranged in a flat configuration, a PV panel having a series of eight PV elements arranged in a flat configuration, and a PV panel assembled from the amplifying structure of FIG. 13A and eight PV elements, in accordance with one or more embodiments; and

FIG. 14 is a top plan view of another example of an amplifying structure, in which reflective surfaces positioned along concave crests have a convex shape protruding from the wall portions, in accordance with one or more embodiments.

### DETAILED DESCRIPTION

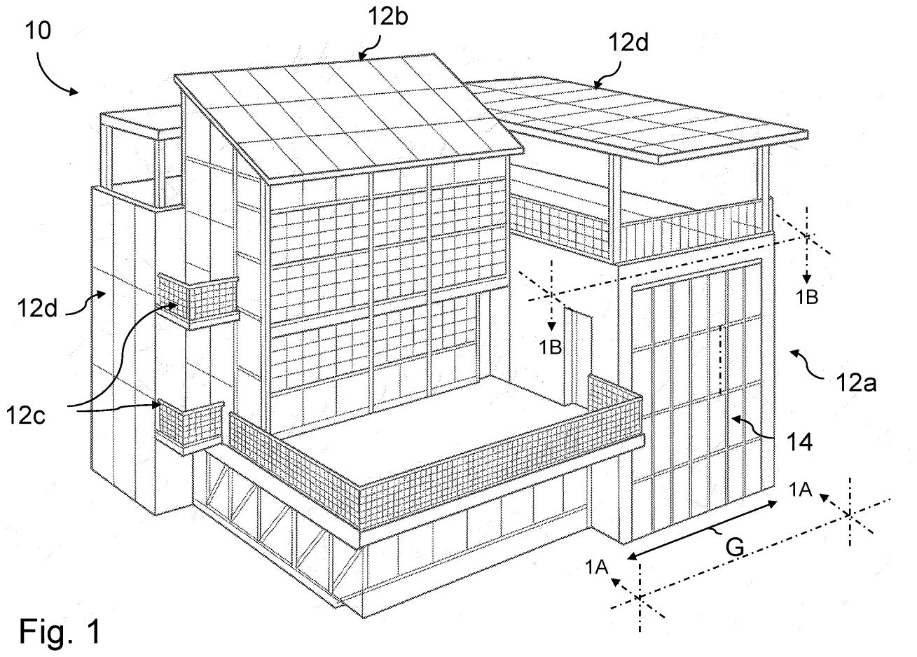

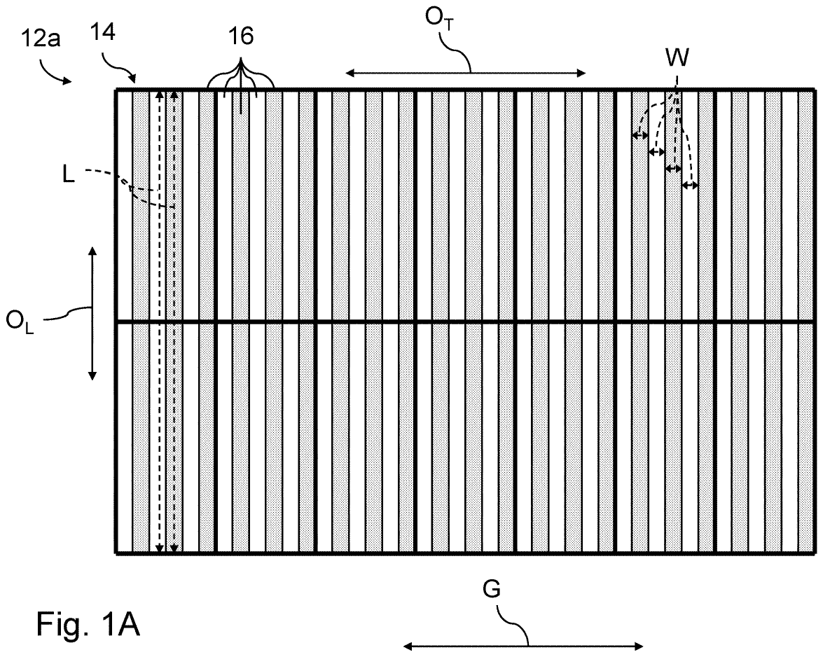

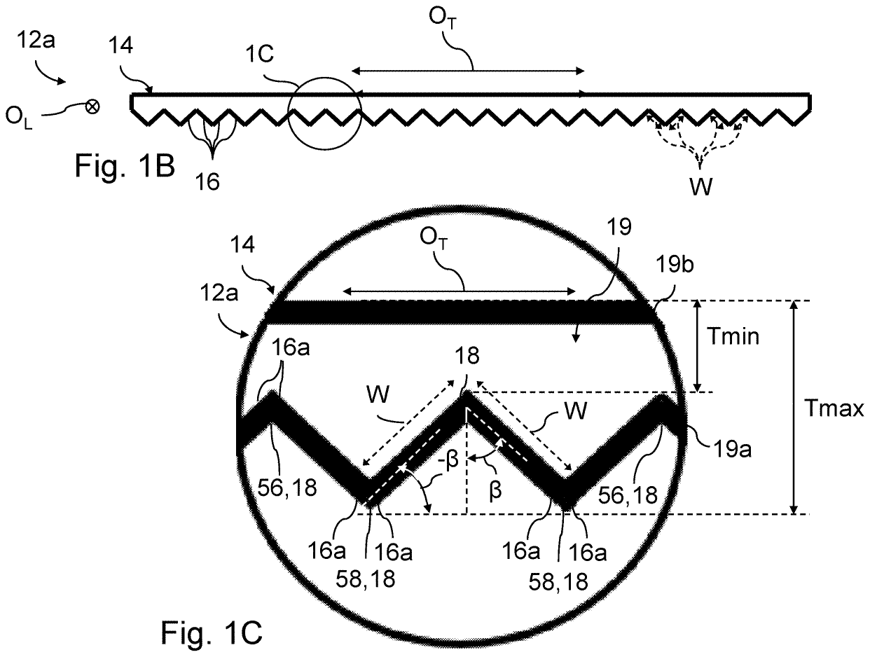

FIG. 1 shows an example of an example of an infrastructure 10, in accordance with one or more embodiments. In this example, the infrastructure 10 is provided in the form of a commercial building. The commercial building can be an office building, a retail building, a hotel building, an industrial building, a warehouse building, a data center building, a community building, and the like. However, in some other embodiments, the infrastructure 10 can be a residential building such as a home, a multi-residential building, a lodge, a cabin, or any other residential building. Moreover, buildings other than commercial or residential can be of interest as well. For instance, the infrastructure can be a part of a solar park (floating or non floating), solar fences, agrovoltaic panels, and other surfaces.

As shown, the infrastructure 10 has a number of infrastructure portions 12 such as wall portions 12a, roof portions 12b, sun shield portions 12c, rain curtain portions 12d, skylight portions 12e, and the like. It is intended that the photovoltaic (PV) panel 14 disclosed herein can be integrated to any of these infrastructure portions. For example, the PV panel 14 can be made integral to these infrastructure portions, or made to retrofit to existing infrastructure portions, depending on the embodiment. Accordingly, the PV panel 14 can be a building-integrated photovoltaic (BIPV) panel.

It is intended that the PV panel 14 can be made opaque for some of these infrastructure portions, such as wall portions 12a, roof portions 12b, and sun shied portions 12c. In some other embodiments, the PV panel 14 can be made transparent for some infrastructure portions as well, including, but not limited to, skylight portions 12e. The opaqueness or transparency of the PV panel 14 can be modified by selecting an appropriate solar cell technology for the PV panel 14. PV panels 14 can include one or more different photovoltaic solar cells (which may be referred to as “PV elements” herein). The choice of the appropriate solar cell technology for the PV panel 14 can also be based on a desired resistive or compressive strength, a price per surface area, a target efficiency, to name only a few examples.

For instance, some PV panels 14 involve a crystalline silicon cell technology for the PV solar cells. It is known that crystalline silicon cells can be integrated into building roofs or walls using mounting systems including, but not limited to, smart mounting systems, which replace the sections of the roof or wall while keeping its integrity intact. This type of integration does not account for large investments and provides a relatively high efficiency. Another option of integration is the replacement of roof or wall tiles with crystalline silicon cells. In some embodiments, the crystalline silicon cells can be coated with an anti-reflective coating, which can enhance the capture of solar energy and provide superior efficiency. At this moment, it is believed that crystalline silicon has the highest energy conversion efficiency among all solar cell technologies. In some other embodiments, the PV solar cells of the PV panels 14 are based on thin film solar cell technologies. Thin film solar cells can be used in case of considerable weight constraints for the building. In such cases, the building envelope is unable to support the weight of crystalline silicon integration, leading to high demand for thin film integrated installation. Thin film is advantageous as it can be used for curved surfaces owing to its superior flexibility. Other solar cell technologies include advanced integrated photovoltaic manufacturing technologies such as dye-sensitized cells (DSC) and organic photovoltaics (BIOPV). The PV panel presented in this disclosure can include, but is not limited to, any one of the above-mentioned solar cell technologies, or any suitable combination thereof. The PV panels 14 referred to in this disclosure can be flat PV panels, or curved PV panels, depending on the embodiment. Other types of coating can be used. For instance, coatings incorporating quantum dots, luminescent down-shifting (LDS), and the like, can be used to generate more photons to be captured by the PV elements, thereby increasing their electricity production.

Referring now to FIG. 1A which shows a side elevation view of one of the wall portions 12a of the infrastructure 10 of FIG. 1, the PV panel 14 has a number of PV elements 16 each having a length L extending along a longitudinal orientation O_{L}. In this example, the PV elements 16 are aligned to one another along the longitudinal orientation O_{L}. Also depicted, the PV elements 16 are spaced relative to one another along a transverse orientation Or which is generally normal to the longitudinal orientation O_{L}. It is intended that for better results in at least some geographic circumstances, the longitudinal orientation O_{L} of the PV panel is oriented vertically relative to the ground level G. However, in some other embodiments, the longitudinal orientation O_{L} can be oriented obliquely or horizontally relative to the ground level G.

As best shown in FIG. 1B, which shows a top plan view of the wall portion 12a, and FIG. 1C which is an enlarged inset of FIG. 1B, each PV element 16 is inclined about a corresponding length L thereof. Moreover, transverse widths W of the PV elements 16 form alternating positive and negative non-null angles ±β relative to the transverse orientation O_{T}. In any way, the non-planar surface profile formed by the alternatingly inclined PV elements 16 has a transverse cross-section which defines a W-shape, such as shown in FIGS. 1B and 1C. The non-null angles ±β can differ from one embodiment to another. For instance, in the depicted embodiment, the alternating positive and negative non-null angles ±β relative to the transverse orientation Or are about 45 degrees and −45 degrees. In some other embodiments, it may be preferable to have the alternating positive and negative non-null angles β relative to the transverse orientation Or set to about 40 degrees and −40 degrees to increase sunlight daily coverage, as will be discussed below. In some preferred embodiments, the alternating angles range between 30 degrees and 50 degrees relative to either side of a transverse plane.

As depicted in this embodiment, proximate longitudinal edges 16a of any two adjacent PV elements 16 are abutted to one another. The PV elements 16 thus form a succession of concave crests 56 and convex crests 58 each extending along the longitudinal orientation O_{L}. In some specific embodiment, the proximate longitudinal edges 16a of adjacent PV elements 16 are sealed or otherwise coupled to one another to form a solid, free-standing structure. For instance, a longitudinal sealing element 18 can be provided at a longitudinal interface between any two adjacent of the PV elements 16. Longitudinal sealing elements 18 can thus be provided along the concave crests 56 and along the convex crests 58, depending on the embodiment. In some other embodiments, the longitudinal edges 16a of any two adjacent PV elements 16 may not be sealed to one another. In fact, they can be spaced apart from one another along the transverse orientation O_{T}. In these embodiments, the sealing of the PV panel 14 can be achieved using a sealed frame on which the PV elements 16 rests, for instance. Other techniques to achieve a hermetic protection or a structural coupling can also be achieved in some other embodiments as will appear to the skilled reader.

In the illustrated embodiment, the PV panel 14 can include a reflective chamber 19 having one or more reflective surface(s) and inside which the PV elements 16 are mounted. As such, light entering the reflective chamber 19 bounces within the reflective chamber 19 via the reflective surface(s). The bouncing of the light can translate into a repeated exposition of the PV elements 16 to one or more reflections of the light within the reflective chamber 19. As shown, the reflective chamber 19 has a first wall 19a to which the PV elements 16 are mounted. Generally, the first wall 19a is optically transparent to let sunlight pass therethrough. The reflective chamber 19 shown in this embodiment is also provided with a second wall 19b which extends longitudinally and transversally. The second wall 19b is located illuminatingly downstream from the first wall 19a. In other words, the sunlight typically reaches the first wall 19a before it reaches the second wall 19b. In these embodiments, the second wall 19b can be optically reflective. In this way, one or more reflective surfaces of the second wall 19b can favor the bouncing of the light within the reflective chamber 19 to increase the chances of photons being absorbed and transformed into electricity by the PV elements 16. In some examples, the thickness of the PV panel 14 can be given by Tmax, which is the spacing between the convex crests 58 and the second wall 19b. As shown, the distance within the reflective chamber 19 can be as thin as Tmin, which is defined as the distance separating the concave crests 56 and the second wall 19b.

FIG. 2 shows an example where the PV panel 14 is provided with a frame 20 to which the PV elements 16 are directly or indirectly mounted. Moreover, it is intended that the PV elements 16 can be permanently or removably (collectively or individually) mounted to the frame 20. As illustrated in this specific embodiment, the frame 20 includes two longitudinal stringer members 21. In this case, two transverse members 22 are used to connect the stringer members 22 to one another. Although, in some other embodiments, the transverse members 22 can be omitted. As shown, the stringer members 21 each has a corresponding succession of first seats 24a and second seats 24b alternating with one another. As the first seats 24a are meant to receive every other one of the PV elements 16 forming either one of the positive and negative non-null angles β, the second seats 24b can receive the remaining PV elements 16 forming the other one of the positive and negative non-null angles β. In this example, the frame 20 includes only peripheral members. However, in some other embodiments, the frame 20 is a full seating structure being hermetic on its own, with for instance first and second walls linking the peripheral members to one another. In these embodiments, the PV elements 16 can be deposited on respective ones of the first seats 24a and second seats 24b. The deposition of the PV elements 16 on the first and second seats 24a and 24b can include an adhesive or other attaching means to ensure that the PV elements 16 are properly attached to the frame. Moreover, such adhesive or attaching means is selected to sustain high temperatures if needed.

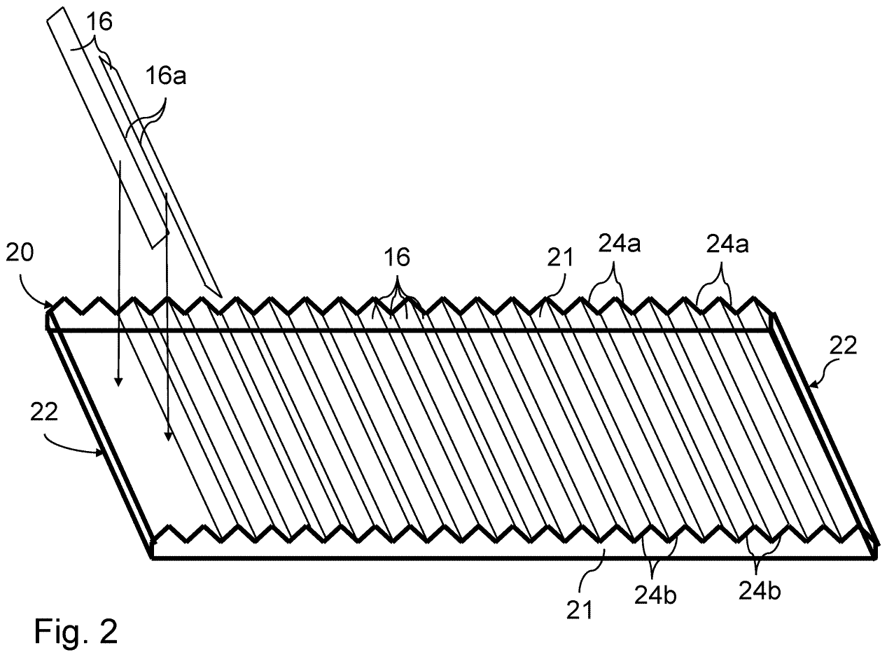

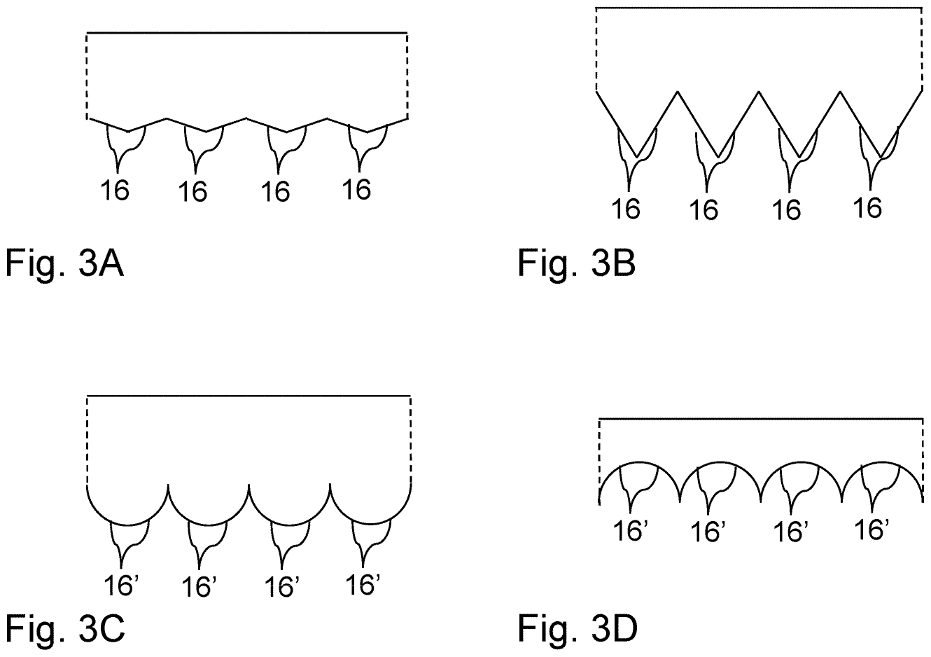

It is intended that the PV elements 16 can be mounted to the frame 20 via actuators (not shown) which are configured for changing the alternating positive and negative non-null angles β which are formed between the transverse widths W of the PV elements 16 and the transverse orientation Or. The actuators can be mechanical actuators such as pneumatic actuators, or electromechanical actuators such as piezoelectric devices, to name only a few examples. In other words, the actuators can be used on the go to modify the angles β or the degree of inclination/tilting of the PV elements about their respective lengths L. FIGS. 3A and 3B show different embodiments of PV elements inclined to different angles about their respective lengths. Such different zigzag or W-shape patterns can be set at the time of manufacture, or else be modified on the go using the actuators described above. In any case, the actuators are options only, as they can be omitted in some embodiments. Also shown in these embodiments is that the PV elements 16 have an elongated flat shape. In some other embodiments, such as the ones shown in FIGS. 3C and 3D, the PV elements 16′ can have an arcuate or otherwise curved shape, with either concave or convex profiles, thereby forming undulated profiles.

It is understood that one or more PV panel(s) can be part of a PV system including, but not limited to, electrical conductors electrically connecting (either in series or in parallel) some or all of the PV elements to one another, an electricity managing device electrically connected to at least some of the electrical conductors to draw and manage electricity generated by the PV elements and conducted thereto via the electrical conductors. Examples of such electricity managing devices are disclosed below.

The following paragraphs present theoretical conjectures which can support the increased efficiency of the BPIV panels and systems described in this disclosure.

The literature generally takes into consideration sunlight power order data integrated into sophisticated models for projecting light rays onto a solar module. To do so, an estimation of the PV panel time of exposure to the sun was over the course of a day was made. The time method presented below may not give the exact power value of light radiation on a PV panel, but can provide a good indication as to how long the sun optimally irradiates the PV panel.

Modern simulation tools allows the determination of the projection of the sun's cardinal position (polar coordinates) of the sun at its winter and summer solstices, as well as the sun's elevation (azimuth) for the same periods. The vantage point is in the center of the city of Montreal, Canada. From these first simulation tools, the average solar irradiance time for a location in central Quebec can be determined. Although the irradiance in relation to the sun's azimuth was not taking into account, as the PV panels are positioned vertically to the ground level, the calculations presented herein were found to be satisfactory.

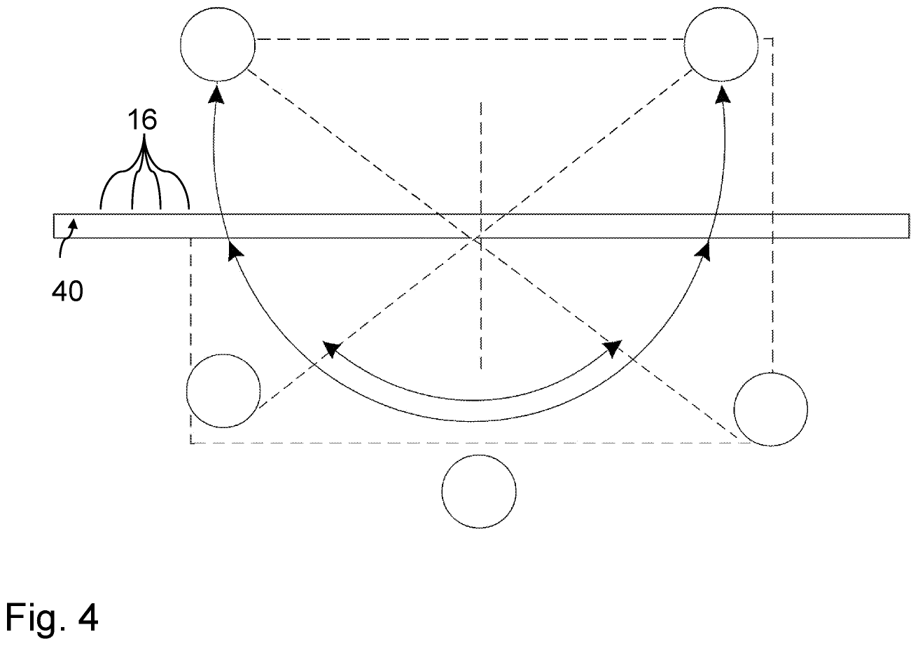

The results are directed to a PV panel installed on a vertical wall in downtown Montreal. Theoretically, if the sun is perfectly south at noon (12 h), it would be at 60° from noon to the east at sunrise and at 60° from noon to the west at sunset at winter solstice. In summer, the angle is greater, as it would be 125° East at sunrise and 125° West at sunset. The angle of the sun in relation to its elevation also has an influence on a solar panel's insolation. As it varies from 18° at winter solstice to 65° at summer solstice, but since this dimension is same for a flat panel as for the PV panel disclosed herein, as both are positioned vertically on a wall. Therefore, the azimuth variable is removed from the calculations. Table 1 shows the results for a conventional PV panel 40 having PV elements 16 laid flat on a vertical wall with the sun at 90° to the wall, as schematized in FIG. 4. The circles showing different positions of the sun as it moves in the sky relative to the conventional PV panel 40. The bottom circle position shows a south position of the sun.

TABLE 1
Results for a conventional PV panel laid flat on a vertical
wall with the sun at 90° to the wall
Surface unit = 120 = 100% of surface
Irradiance = 54.3% of the optimum

| Winter | | |
|---|---|---|
| Sunrise | Sunset | Total |
| 7.5 | 16.5 | 9 |
| Irradiance | | |
| 7.5 | 16.5 | 9 |
| Summer | | |
| Sunrise | Sunset | Total |
| 4.5 | 19.5 | 15 |
| Irradiance | | |
| 7.5 | 16.5 | 9 |
| Orientation | % of production | |
| 10 | 8 | Irradiance at Sunrise |
| 20 | 15 | |
| 30 | 25 | |
| 40 | 40 | |
| 60 | 55 | |
| 60 | 60 | |
| 70 | 70 | |
| 80 | 80 | |
| 90 | 90 | |
| 100 | 100 | Noon |
| | 54.3 | Average |

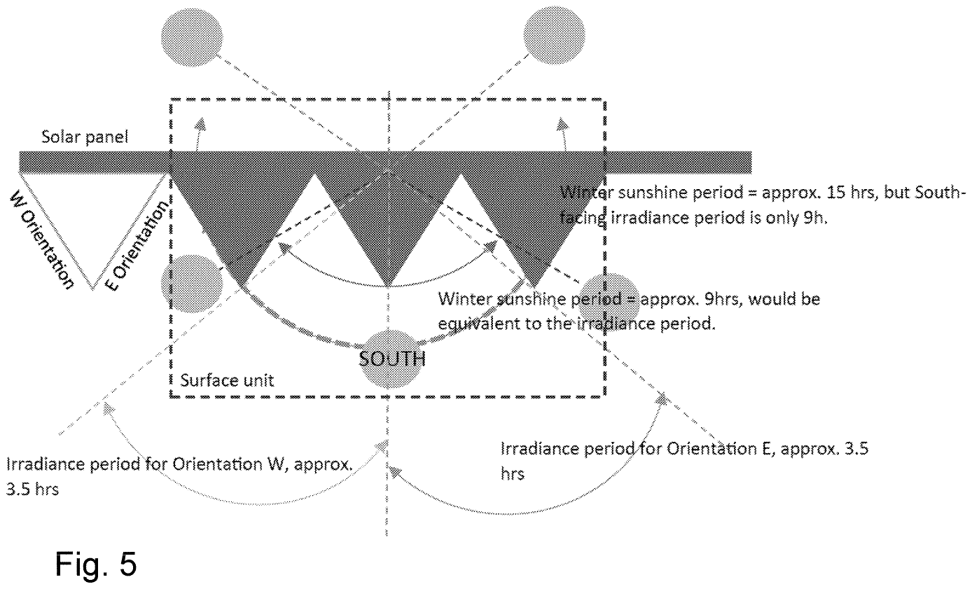

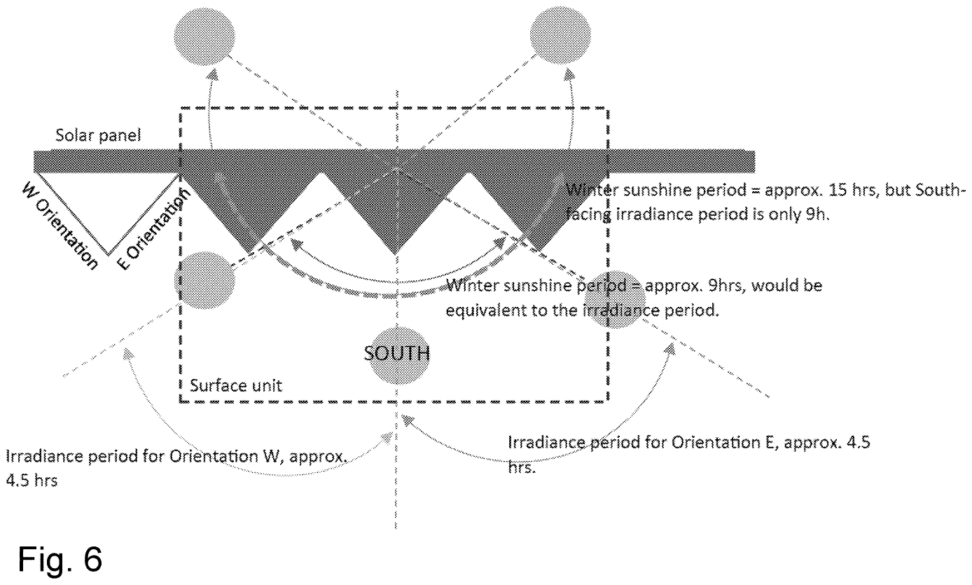

FIGS. 4 and 5 show the irradiance patterns for two different embodiments of the PV panel disclosed herein, one with positive and negative non-null angles of about 40 degrees and the other with angles of about 45 degrees. It is noted that the 45° angle of the angular surfaces may not be optimal, as irradiance is lost at the extremes of sunrise and sunset. The optimum angle is therefore that of the winter solstice at sunrise and sunset, i.e., around 40°. This angle relates to the one shown above for the positive and negative non-null angles relative to the transverse orientation Or. If 9 h of daily production is equal to 100% of the estimated production in a day of orientation, this production period still needs to be weighted by an irradiance ratio varying over the day. Because the sun doesn't shine on a PV panel at the same angle all day long. To do this, an approximate average duration of sunlight on the solar panel in relation to the sun was calculated. This average would be comparable to a time when the panel is “best” oriented to the sun. This average would be comparable to a period of time when the panel would be “best” oriented to the sun, and when its output would be “best.” In this way, one could simulate the time the panel would produce at its maximum capacity at 90° orientation. Table 2 below shows that the yield of a solar panel varies according to its angle to the sun. At 90° to the panel, the yield is 100%. If the different % efficiencies in are outputted in relation to angle, a theoretical average of 54.3% is obtained on a sunny day. The panel would have a “performance” of 4.88 hrs per day for a maximum sunshine duration of 9 hrs.

The PV panel disclosed herein can be provided in the form of a non-Lambertian surface or system, meaning that it does not exhibit Lambertian behavior. In other words, the non-Lambertian PV panel does not reflect, emit, or capture light uniformly in all directions according to Lambert's cosine law. Instead, its optical response is directionally dependent, producing anisotropic (non-uniform) angular behavior, which can allow for an increase of the number of hours during which electricity can be satisfactorily produced.

TABLE 2
Results for a PV panel having a W-shaped geometry as disclosed
herein laid on a vertical wall with the sun at 90° to the wall
Surface unit = 6 × 26 = 156 = 30% of additional surface
Irradiance = 71%-22% of additional irradiance

| Summer | | |
|---|---|---|
| Sunrise | Sunset | Total |
| 7.5 | 16.5 | 9 |
| Irradiance | | |
| 7.5 | 16.5 | 9 |
| Summer | | |
| Sunrise | Sunset | Total |
| 4.5 | 19.5 | 15 |
| Irradiance | | |
| 7.5 | 16.5 | 9 |
| Orientation | % of production | |
| 40 | 40 | Irradiance at Sunrise |
| 50 | 55 | |
| 60 | 60 | |
| 70 | 70 | |
| 80 | 80 | |
| 90 | 90 | |
| 100 | 100 | Noon |
| | 71 | Average |

If 9 hours of irradiance is equal to 100% of the estimated production for a full-SOUTH day, in the case of the PV panels disclosed herein, this production period can be weighted by an irradiance ratio varying day for all the PV panel's peaks, because the PV elements are advantageously oriented towards the sun, unlike a panel laid flat on the wall. In this way, the time the panel would produce at its “optimum” capacity is estimated. It is observed that the ratio of a flat panel is 54.3%, whereas in the case of the PV panel disclosed herein, the ratio is of 71%. What's more, the actual exposed surface is 30% greater than the flat surface. Finally, a theoretical performance for the PV panel disclosed herein was determined to be 8.31 h per day at its maximum for a maximum sunshine duration of 9 hrs.

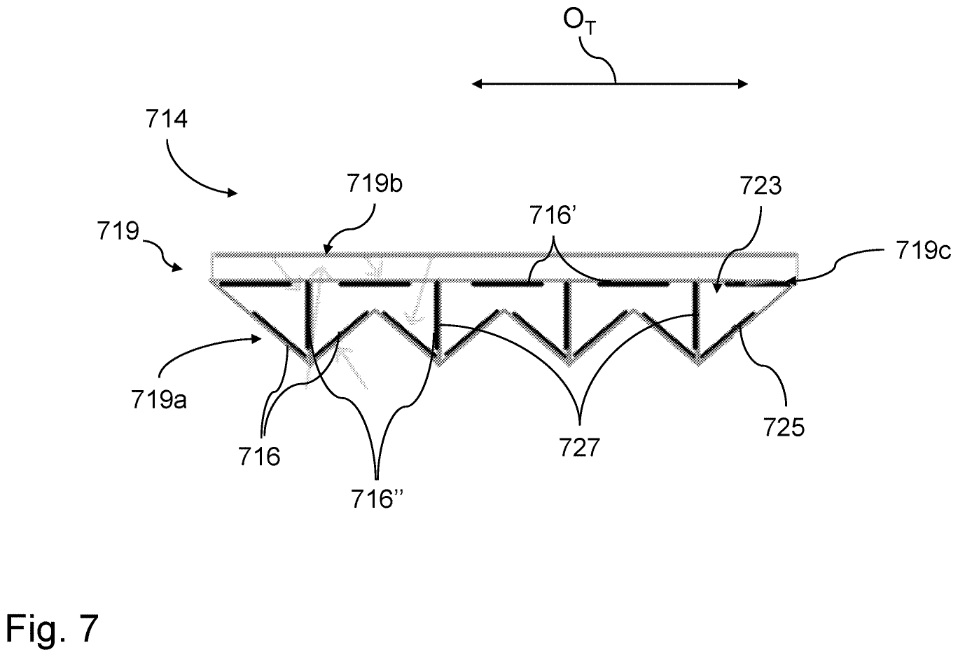

FIG. 7 shows an example of a PV panel 714, in accordance with an embodiment. As depicted, the PV panel 714 has a reflective chamber 719 having one or more reflective surfaces (hereinafter “the reflective surface 723”). The PV elements 716 are mounted to the reflective chamber 719, and preferably thereinside. The PV elements 716 are oriented in alternating positive and negative angles relative to the transverse orientation are referred to as “the first set of PV elements 716” in the paragraphs below. As such, at least one wall of the reflective chamber 719 is generally provided with a discontinuous surface bearing a W-shaped cross-sectional area to receive the PV elements 716 of the first set, such as shown in FIG. 7.

In certain embodiments, the reflective surfaces 723 are permanently or removably mounted to the at least one wall of the reflective chamber 719. In some other embodiments, the reflective surfaces 723 can be made integral to one or more walls of the reflective chamber 719. In any case, the reflective surfaces 723 are made to be optically reflective in a region of the electromagnetic spectrum at which the PV elements are designed to operate. For instance, this region of the electromagnetic spectrum can at least partially scan the region covered by sunlight. This region may include at least a portion of the ultraviolet region, the visible region, the infrared region of the electromagnetic spectrum, or a combination thereof. In preferred embodiments, the reflective surface has a reflectivity exceeding 80%, preferably exceeding 95%, and most preferably exceeding 96%. Thanks to the reflective surface, light entering the reflective chamber can bounce within the reflective chamber via the reflective surface. Accordingly, the PV elements mounted inside the reflective chamber are repeatedly exposed to one or more reflections of the light within the reflective chamber. It was found that each reflection of the light within the reflective chamber can increase the probability of photons reaching corresponding PV elements, and as a result, can increase electricity production as much as two-, three-fold or more, according to early simulation results.

As shown in this example, the reflective chamber has a first wall and a second wall which extend longitudinally and which rest opposite to one another across the transverse orientation Or. In this embodiment, the PV elements of the first set are mounted to the first wall. Preferably, the PV elements are mounted to an interior face of the first wall. Accordingly, the first wall has the W-shaped cross-sectional area discussed above as depicted. It was found convenient to make sure the first wall is optically transparent to the relevant region of the electromagnetic spectrum whereas the second wall is made to be optically reflective to the relevant region. The optical transparency of the first wall can stem from the first wall being made of an optically transparent material such as glass. More specifically, the reflective surface can be mounted to or made integral to the second wall depending on the embodiment. In any way, the reflective surface faces the interior of the reflective chamber to reflect light propagating through the first wall back towards the PV elements of the first set. The first wall has an optical transparency exceeding 50%, preferably above 75% and most preferably above 85%, depending on the embodiment.

In some embodiments, such as the one illustrated in FIG. 7, the first wall has a one-way coating 725 deposited thereon. The one-way coating is configured for allowing light outside the reflective chamber to enter the reflective chamber via the first wall. Moreover, the one-way coating is configured for reflecting light inside the reflective chamber back inside the reflective chamber. In other words, light impinging on the reflective chamber can easily enter the reflective chamber, but light exiting the reflective chamber can be strongly back inside the reflective chamber. As such, the amount of light exiting the reflective chamber via the first wall can be insignificant and even negligible in some embodiments. Preferably, the one-way coating is deposited on an internal face of the first wall. It is known that such a thin film coating may not be perfect. However, each photon which is prevented from leaving the reflective chamber and which is reflected towards other PV elements can contribute to enhance electricity production. In some other embodiments, an anti-reflective coating is used instead of or additionally to the one-way coating.

Still referring to FIG. 7, the PV panel 714 further has a third wall 719c which extends longitudinally and which is positioned between the first wall 719a and the second wall 719b. In this specific embodiment, the third wall 719c extends along the transverse orientation in a manner parallel to the first and second walls 719a and 719b. As illustrated, the PV panel 714 has a second set of PV elements 716′ which is mounted to the third wall 719c. In some embodiments, the PV elements 716′ of the second set fully covers the third wall 719c. However, in some other embodiments, the PV elements 716′ of the second set only partially covers the third wall 719c. In any case, the third wall 719c is made of an optically transparent material to let sunlight pass through from both sides, thereby allowing additional chances that a photon satisfactorily impinges on one of the PV elements 716′ of the second set to generate additional electricity. The spacing between the first wall 719a and the third wall 719c, as well as the spacing between the second wall 719c and the third wall 719c, can be modified to increase the number of reflections occurring inside the reflective chamber 719. For instance, any one of these spacings can range between 5 mm and 20 cm, more preferably between 1 cm and 10 cm, and most preferably between 2 cm and 5 cm.

Chamber partitions 727 which extend longitudinally and which connect the first and second walls 719 and 719b to one another can also be provided, such as shown in FIG. 7. Depending on the embodiment, the chamber partitions 727 can link the second wall to distal or proximal portions of the first wall 719a. As such, the chamber partitions 727 may be positioned to connect to the second wall 719b at peaks or depressions of the first wall 719a. In some circumstances, it can be convenient to mount a third set of PV elements 716″ to one or more of the chamber partitions 727. Again, increasing the number of PV elements within the reflective chamber 719 can increase the probability of having a photon reach one of the PV elements. In embodiments where the chamber partitions 727 are made to be optically transparent, then reflections transmitted through the chamber partitions 727 can still reach PV elements 716, 716′ and 716″ thereacross. In some embodiments, the chamber partitions 727 can be moved as desired using a number of dedicated mechanical actuators.

It is intended that in the depicted embodiment, the angled PV elements 716 of the first set are mounted to the first wall 719a which is optically transparent. However, the PV elements 716′ of the second set may be mounted to the second wall 719b which is optically reflective in some other embodiments. Additionally or alternatively, the second wall 719b can bear alternatingly angled PV elements 716′ forming the W-shape cross-sectional area discussed above. Such an embodiment is particularly interesting when other set(s) of PV elements, such as the second and third sets of PV elements 716″, are mounted inside the reflective chamber 719 for electricity production enhancement purposes.

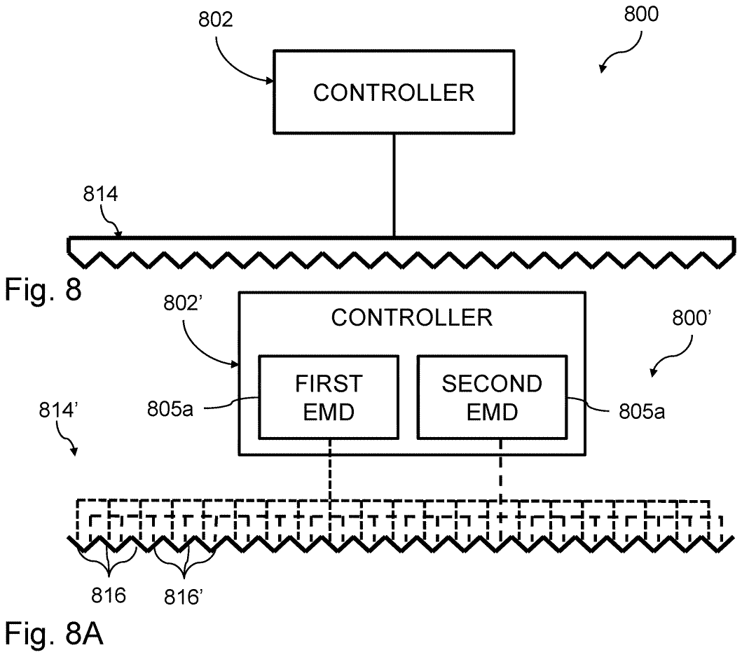

As shown in FIG. 8, in some embodiments, a PV panel system 800 has a PV panel 814 which is communicatively coupled to a controller 802. The controller 802 has a processor and a non-volatile memory having stored thereon instructions which when executed perform some predetermined steps. In some embodiments, the controller 802 is configured for determining actuating instructions for mechanical actuators of the PV panel system. As discussed above, these mechanical actuators can be used to move portions of the PV panel to maximize electricity production and can include embedded strategies such as tracking the sun using a sun tracking sensor, for instance. If executed, the actuating instructions can move the mechanical actuators in a subsequent configuration which has the potential of increasing instantaneous electricity production. The actuating instructions can be determined based on instantaneous readings of sensors communicatively coupled to the controller 802. Examples of such sensors can include, but are not limited to, power meter(s), amperemeter(s), sun-tracking system(s), sun exposition system(s), and the like. The controller 802 can then actuate one or more of the mechanical actuators based on the actuating instructions to move one or more of the PV elements in the subsequent configuration. It is understood that the movement of the PV elements via the mechanical actuators can help efficiently track sunlight to increase electricity production, in some embodiments. In certain embodiments, the step of determining the actuating instructions and the step of actuating the mechanical actuators are performed in real time or quasi-real time based on the instantaneous readings from the sensors. Accordingly, these steps can be iteratively performed in a closed control loop to increase electricity production over time. The closed control loop can be initiated upon detecting presence of sunlight in some embodiments. In these embodiments, the closed control loop may be performed in a continuous manner until it is detected that sun exposition has ended. In some other embodiments, the closed control loop is initiated at a sunrise time and ended at a current time. In some embodiments, the controller 802 is at least partially, and preferably fully, powered by the PV elements. In other words, the PV element(s) generate a sufficient amount of electricity which enables the partial or complete powering of the controller 802.

In some embodiments, the controller includes a trained engine which can determine the actuating instructions based on the instantaneous readings from the sensor(s). For instance, in some embodiments, the trained engine can be trained using supervised learning. Supervised machine learning engines can be based on Artificial Neural Networks (ANN), Support Vector Machines (SVM), capsule-based networks, Linear Discriminant Analysis (LDA), classification tree, a combination thereof, and any other suitable supervised machine learning engine. Such supervised machine learning engines can be trained using a set of reference instantaneous sensor readings and truth value corresponding to the theoretically right decision to undertake to enhance electricity production. Over time, and with an ever-increasing amount of training data, the trained engine can become sentient in the sense that when inputting sensor readings measured in real time or quasi-real time, the trained engine can straightforwardly determining the corresponding actuating instructions to enhance electricity production. However, as can be understood, in some other embodiments, it is intended that the engine can be trained using unsupervised learning. For instance, unsupervised clustering algorithms can be used. Two exemplary methods for improving classifier performance include boosting and bagging which involve using several classifiers together to “vote” for a final decision. Combination rules can include voting, decision trees, and linear and nonlinear combinations of classifier outputs. These approaches can also provide the ability to control the trade-off between precision and accuracy through changes in weights or thresholds. These methods can lend themselves to extension to large numbers of localized features. In any case, some of these engines may require human interaction during training, or to initiate the engine, however human interaction may not be required while the engine is being carried out, e.g., during analysis of an accessed image. See Nasrabadi, Nasser M. “Pattern recognition and machine learning.” Journal of electronic imaging 16.4 (2007): 049901 for further detail concerning such trained engines.

FIG. 8A shows another example of a PV panel system 800′, in accordance with another embodiment. As shown, the PV panel system 800′ has a PV panel 814′ which is communicatively and electrically coupled to a controller 802′. In this specific example, the controller 802 includes at least two different electricity management devices, i.e., a first EMD 805a and a second EMD 805b. Each EMD is electrically coupled to a respective set of the PV elements 816 and 816′ of the PV panel 814′. More specifically, the PV elements 816 facing towards a first orientation are electrically connected to the same electricity management device which is in this case the first EMD 805a. Additionally, the PV elements 816′ facing a second orientation different from the first orientation are electrically connected to the same electricity management device which is in this case the second EMD 805b. It was found that by using multiple dedicated EMDs, the management of the electricity generated by the PV elements 816 and 816′ can be enhanced. Indeed, in some embodiments, the PV elements 816 and the first EMD 805a are connected in series to one another. Similarly, the PV elements 816′ and the second EMD 805b are connected in series to one another. These connections can be made in parallel in other embodiments for instance when higher system current is acceptable, voltage must remain the same, or electricity management requirements dictate it. This electrical independence is particularly beneficial for W-shaped modules, where each facet naturally experiences different irradiance. Indeed, it was found that this dual-device architecture can provide several advantages. For instance, each orientation can operate at its own maximum power point, enabling optimal energy extraction despite different illumination levels across the two surfaces. Moreover, the system may tolerates partial shading: if one set receives less light, its reduced power does not drag down the output of the other set. Additionally, such an architecture can increase reliability and robustness, since no single electricity management device channel is forced to handle mixed, incompatible irradiance profiles.

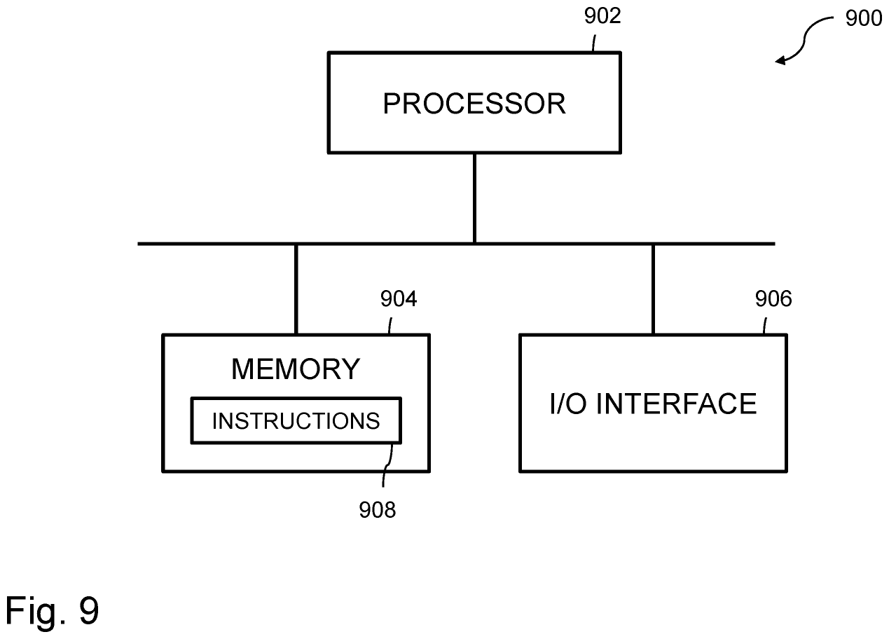

Referring now to FIG. 9, the controller can be provided as a combination of hardware and software components. The hardware components can be implemented in the form of a computing device 900, an example of which is described with reference to FIG. 9. The computing device 900 can have a processor 902, a memory 904, and I/O interface 906. Instructions 908 for operating the PV panel system can be stored on the memory 904 and accessible by the processor 902.

The processor 902 can be, for example, a general-purpose microprocessor or microcontroller, a digital signal processing (DSP) processor, an integrated circuit, a field-programmable gate array (FPGA), a reconfigurable processor, a programmable read-only memory (PROM), a programmable logic controller (PLC), or any combination thereof.

The memory 904 can include a suitable combination of any type of computer-readable memory that is located either internally or externally such as, for example, random-access memory (RAM), read-only memory (ROM), compact disc read-only memory (CDROM), electro-optical memory, magneto-optical memory, erasable programmable read-only memory (EPROM), and electrically-erasable programmable read-only memory (EEPROM), Ferroelectric RAM (FRAM) or the like.

Each I/O interface 906 enables the computing device 900 to interconnect with one or more input devices, such as keyboard(s), mouse(s), sensor(s), or with one or more output devices such as monitor screen(s), external network(s), accessible memory system(s).

Each I/O interface 906 enables the controller to communicate with other components, to exchange data with other components, to access and connect to network resources, to server applications, and perform other computing applications by connecting to a network (or multiple networks) capable of carrying data including the Internet, Ethernet, plain old telephone service (POTS) line, public switch telephone network (PSTN), integrated services digital network (ISDN), digital subscriber line (DSL), coaxial cable, fibre optics, satellite, mobile, wireless (e.g., Wi-Fi, WiMAX), SS7 signalling network, fixed line, local area network, wide area network, and others, including any combination of these.

The computing device 900 and any software application that can be run by the computing device 900 are meant to be examples only. Other suitable embodiments of the controller can also be provided, as it will be apparent to the skilled reader.

It is understood that the performance of the reflective chamber described above can be influenced by a number of parameters. For instance, quality of reflective surfaces is paramount. Examples of the reflective surfaces can include, dielectric coatings, anodized aluminum, and the like. Such reflective surfaces can be lightweight, durable, and cost-effective compared to silver-based mirrors, as their thickness can be below 1 mm. Preferably, at least 95% of incident light is reflected. There may be 5% or less of light absorbed or otherwise scattered at each light reflection. For example, after three reflections, approximately 85.7% of the original light may still be bouncing within the reflective chamber.

The chamber geometry is sized and shaped to ensure that reflected light consistently reaches the PV cells without excessive dispersion or absorption by non-reflective surfaces (e.g., edges or walls). An example three reflections allow sufficient photon concentration while minimizing losses.

Moreover, thermal management is paramount in achieving a workable embodiment. It is intended that the PV panel system described herein can include a cooling mechanism based on passive cooling or active cooling, depending on the embodiment. For instance, cool air may be blown longitudinally between the first and second walls of the reflective cavity. In another example, the PV elements are positioned vertically so natural convection impart at least a little cooling effect. In more complex embodiments, a heat pump can be used to pump heat out of the reflective cavity. All cooling mechanisms can be controlled by the controller and be initiated upon determining that a temperature inside the reflective chamber exceeds a given threshold. Overall, it was found that three sets of reflective surfaces, such as mounted to the second wall, the third wall and the chamber partitions can help control heat buildup without compromising light bouncing within the cavity. Moreover, it was found that adding more reflective surfaces or increasing the number of bounces may complicate manufacturing and increase costs without proportional gains in efficiency.

In a very specific embodiment, each V-section of the first wall has a typical angle of about 40°-70° relative to the transverse plane to optimize photon redirection towards the PV elements. Ultraviolet-resistant silicone-based adhesives can be used for bonding mirrors and glass components in the reflective chamber. Such sealants can be hydrophobic to prevent moisture ingress.

According to some preliminary calculations, the PV panel described herein may reach energy output approximately six times greater than traditional panels. As such, the PV panel described herein has realistic potential to sextuple the energy output of traditional flat panels while addressing condensation, durability, and heat management challenges effectively.

In accordance with another aspect, the solar panel described herein can be integrated with one or more mirrored surfaces on the exterior walls and/or interior walls of the reflective chamber. Bifacial or monofacial PV cells can also be integrated on the exterior and/or interior surfaces of the reflective chamber. A passive or active ventilation system can be used to ensure proper ventilation within the reflective chamber. The ventilation system can be powered by the PV elements of the PV panel, in some embodiments. In some embodiments, one or more of the transparent walls of the reflective chamber can include one or more Fresnel lenses. The reflective chamber can be provided in the form of a resonant cavity to increase light capture and the number of reflections on the PV cells. All the parts of the PV panel, or only some parts thereof, can be movably mounted to the frame. These movable parts can be actuated to more in small or rapid movements to increase light capture and reflection.

In some embodiments, the W-shaped PV panel includes a reflective surface which is mounted at the bottom of the W shape, to increase light capture and reflection on the PV elements. The reflective surfaces typically have an optical reflectivity of about 97% in the sunlight region of the electromagnetic spectrum. As many as fifteen Fresnel lenses can be used in conjunction with each PV element to enhance light capture. The PV elements can be provided in the form of bifacial Passivated Emitter and Rear Cell (PERC) cells having a 24% efficiency on a front face thereof and 25% efficiency on the back face thereof. A self-powered cooling system (e.g., 5 W) can be provided to the PV panel system to cool some or all the parts that may heat during use of the PV panel system. The PV panel and PV panel system described herein can be used in any type of solar panel including, but not limited to, a conventional solar panel, a photovoltaic solar panel, a thermal solar panel, and a BIPV solar panel, and any other suitable types of PV panel or application thereof. It is important to mention that the PV panel and PV panel system described herein may use conventional PV elements providing known and repeatable solar efficiencies. The PV panel and PV panel system described herein is based on the improvements of a frame (e.g., an enclosure) of the PV panel or PV panel system. These improvements aim at increasing the number of light bounces on the PV elements of the PV panel and PV panel system. It is generally accepted that science within 50 years has passed the performance of photovoltaic panels from 10% to 20%. The improvements presented herein may almost double, in some circumstances, instantaneously the performance of photovoltaic panels when using the frame and/or enclosure described herein. Ongoing research aims at greatly improving these performances, with particular emphasis on some variants including, but not limited to, reflective chambers, AI-powered controllers, Fresnel lenses, resonant cavities, ventilation and/or cooling systems. These innovations aim to generate a new solar energy sector in order to accelerate their development in but quickly contribute to reducing CO2 emissions.

### Example 1—Bifacial Panels and Reflectivity-Enhancing Base Panels

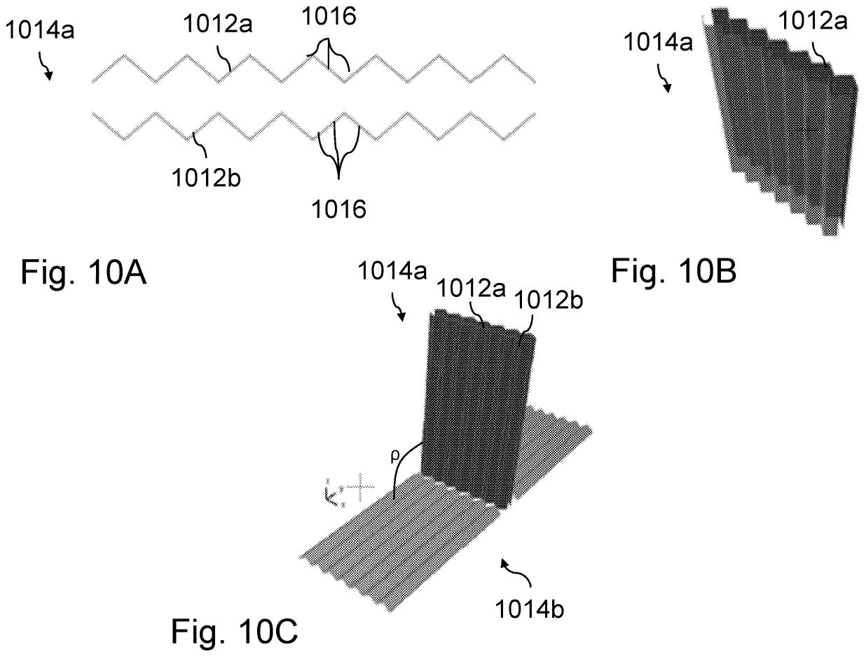

Conventional solar panels are typically flat and oriented to maximize exposure to direct sunlight. However, such configurations often suffer from suboptimal performance due to limited exposure angles and reduced efficiency during low-light conditions and/or when sunlight strikes at oblique angles. Bifacial panels arranged in a W-shaped geometry, which can capture light from both front and rear surfaces, offer improved energy yield, especially when combined with reflective surfaces that enhance rear-side illumination. An example of such a bifacial panel 1014a is shown in FIGS. 10A and 10B. As shown, the bifacial panel 1014a has two wall portions 1012a and 1012b facing each other. Each of the wall portions 1012a and 1012b has a series of alternating PV elements 1016 collectively forming a W-shape. In this example, there is proposed PV panel configuration having: the bifacial panel 1014a which can enhance exposure to sunlight throughout the day; and base panels 1014b placed at the base of the bifacial panel 1014a. As shown in this example, the base panels 1014b also have a W-shaped configuration. The base panels 1014b are constructed from white-colored photovoltaic materials to serve a dual purpose including: a first function of generating electricity; and a second function of acting as a high-reflectivity surfaces to reflect sunlight onto the bifacial panel 1014A. It was found that such a configuration can optimize solar energy capture by leveraging geometric orientation and reflective enhancement, particularly in cold climates with high reflectivity conditions (e.g., snow). Reflectivity refers to the fraction of solar radiation reflected by a surface. White or light-colored surfaces (e.g., snow, white gravel) exhibit high reflectivity values (0.3 to 0.9), while dark surfaces (e.g., asphalt) have low reflectivity (0.05 to 0.15). This example proposes high-reflectivity horizontal panels to reflect light onto vertical bifacial panel, increasing rear-side irradiance and overall energy yield.

The angle ρ between the bifacial panel 1014a and the base panels 1014b can change from one embodiment to another. For instance, the bifacial panel 1014a may be positioned vertically (perpendicular to the ground) whereas the base panels 1014b may be positioned horizontally (parallel to the ground). Although such a right angle between the bifacial panel 1014a and the base panels 1014b may be appropriate, computer simulations showed that, during the summer solstice, the optimal inclination of the base panels 1014b relative to the bifacial panel 1014a can be about 85°, facing East-Northeast. However, during the winter solstice, the optical inclination can be about 87°, facing Southeast. In some embodiments, a compromise angle of 45° was selected to balance direct solar capture and reflectivity reflection, weighted 70% toward reflectivity and 30% toward direct capture. In this example, Copper Indium Gallium Selenide (CIGS) cells were chosen for their: high performance in low light, lower temperature sensitivity, flexibility and lightweight properties.

### Example 2—Multiplication of Folds and Transition to Nano-Scale

The present example relates to photovoltaic modules incorporating W-shaped geometries and nanostructured surface features to enhance solar energy capture and conversion efficiency. More specifically, this example pertains to a solar panel architecture that can leverage macroscale geometric optimization and nanoscale optical enhancements, including diffraction gratings and/or plasmonic structures, to improve light absorption and energy yield.

Indeed, the solar panel design comprising a series of W-shaped folds is configured to optimize the angle of incidence of sunlight across multiple facets, thereby increasing the duration and quality of solar exposure throughout the day. Each fold of the W-shaped geometry can be oriented to intercept sunlight at varying angles, allowing for improved capture of both direct and diffuse solar radiation. The W-shaped geometry can increase the effective active surface area relative to the projected footprint, enabling a higher density of photovoltaic cells per unit area. This configuration also facilitates the integration of bifacial panels and base reflectors surfaces (e.g., reflective base panels) to redirect additional light toward the bifacial panel layers.

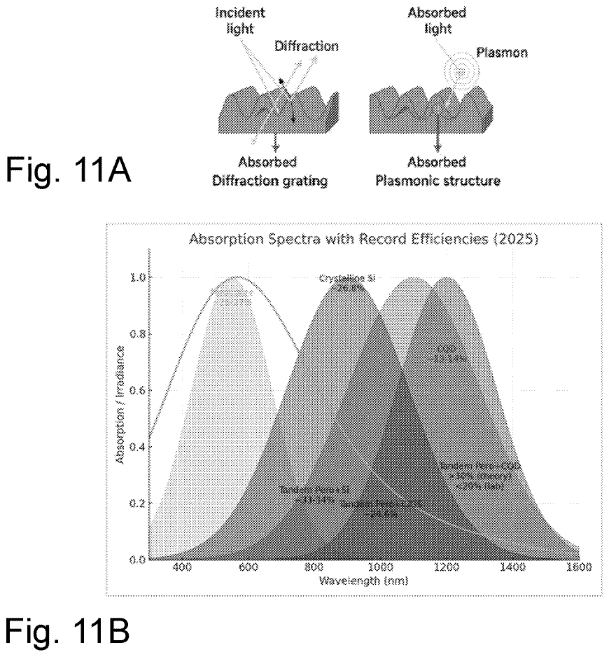

To further enhance the performance of such panels, this example further contemplates the multiplication of W-shaped folds from the macroscopic scale (e.g., centimeters) to the nanometric scale (e.g., nanometers). At macro scale, the folds can function as discrete inclined surfaces governed by geometric optics. As the fold dimensions approach the wavelength of incident light (e.g., 400-1100 nm), the behavior transitions to wave optics, introducing phenomena such as diffraction, interference, and/or plasmonic resonance. More specifically, at nanoscale, the W-shaped folds can act as diffraction gratings. Such diffraction gratings can separate, and redirect light based on wavelength. The diffraction gratings can also increase the optical path length within the active layer. The W-shaped folds can also act as or plasmonic structures to concentrate electromagnetic fields via surface plasmon resonance, enhancing local light absorption. These phenomena are illustrated in FIG. 11A.

Such nanostructures may be fabricated using existing techniques such as nanoimprinting, lithography, laser etching, to name a few examples. Materials suitable for plasmonic enhancement include metallic nanoparticles (e.g., Ag, Au, Al), with aluminum offering cost and performance advantages due to its resonance in the ultraviolet spectrum and abundance. This example is compatible with various photovoltaic technologies, particularly those with thin active layers that benefit from extended optical paths. For instance, Perovskite solar cells are found to exhibit strong compatibility due to their thin layers and broad visible spectrum absorption. Colloidal Quantum Dot (CQD) cells can extend absorption into the deep infrared, offering theoretical efficiencies exceeding 30%. CIGS cells can benefit primarily in ultra-thin configurations, with moderate gains from plasmonic enhancements. Crystalline silicon is known to be less responsive to plasmonic effects due to its inherent thickness and absorption efficiency.

At this stage, empirical and theoretical analyses indicate that the combination of W-shaped geometry, reflectivity panel enhancement, and plasmonic nanostructuring can yield significant improvements in energy production. For instance, some comparative studies show that W-shaped panels outperform flat panels by a factor of ~1.6-1.7×; reflective panels and bifacial configurations such as those discussed at Example 1 can add ~10-30% gain; and plasmonic enhancements may even contribute to an additional ~10-20%. Cumulatively, the total efficiency gain may reach ~2.0-2.6× compared to conventional flat panels under similar environmental conditions. It was thus found that by integrating macroscale geometric optimization with nanoscale optical enhancements, enhanced performance can be achieved. The W-shaped geometry increases solar capture through improved angular exposure and surface area, while nanostructured folds function as advanced optical elements that manipulate light at the sub-wavelength level to absorb more sunlight, such as shown in FIG. 11B. Indeed, a preferred embodiment combines W-shaped macro geometry with plasmonic nanostructures applied to perovskite-CQD tandem cells, offering extended spectral coverage and high theoretical efficiency. This hybrid design can represent a significant advancement in photovoltaic technology, enabling the development of next-generation solar modules with superior performance.

### Example 3—Testing Comparing Performance of Conventional PV Elements Versus PV Elements Inclined in a W-Shaped Geometry with and without Use of Additional Reflective Surfaces Between the PV Elements

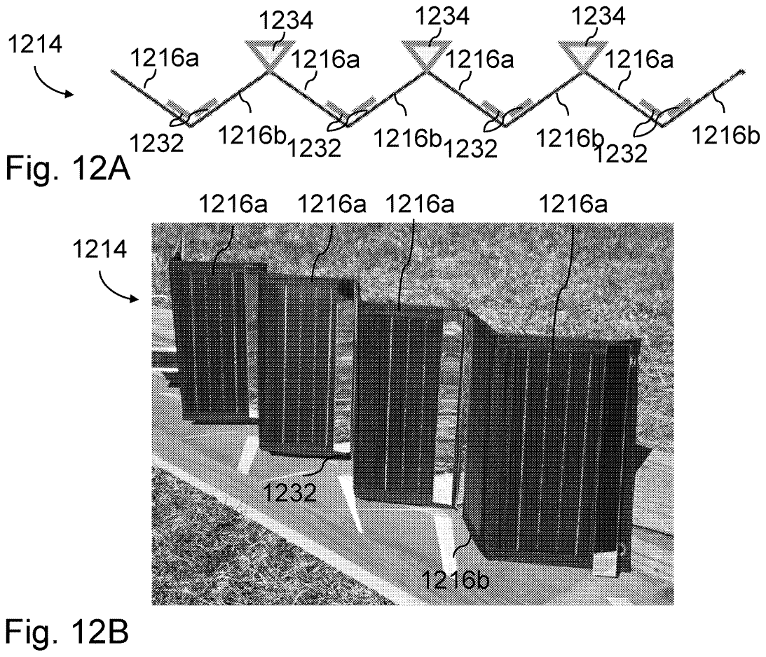

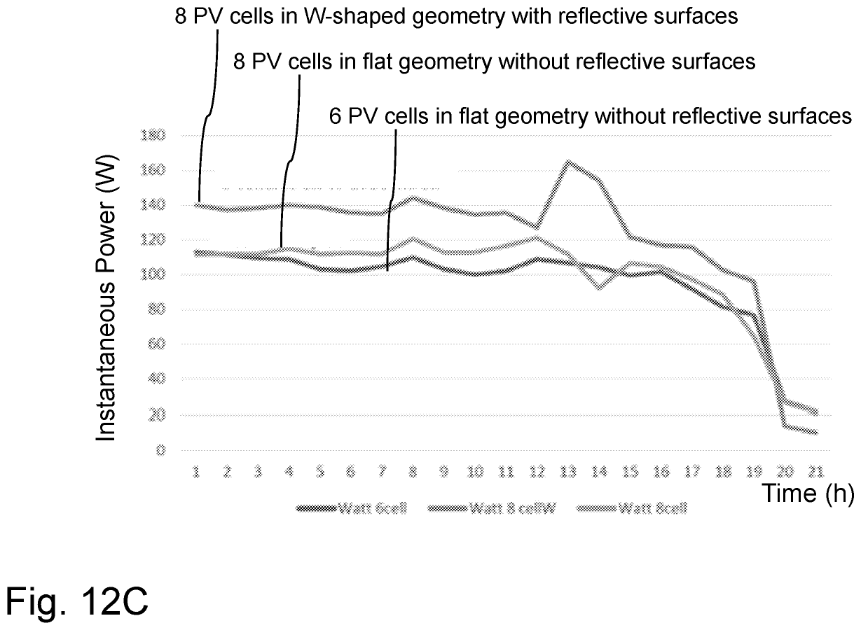

The present example relates to photovoltaic energy conversion, specifically to photovoltaic modules having a W-shaped geometry and optional reflective elements to increase energy yield under oblique and diffuse insolation, along with associated electrical interconnection topologies that mitigate partial-shading losses. As used herein, a W-module 1214 is a photovoltaic (PV) module in which cell-bearing substrates are inclined or formed to provide two opposing, inward-facing facets that meet at an interior concave crest and diverge toward exterior convex crests, yielding an overall cross-section resembling the letter W. In contrast, in the following paragraphs, a “flat module” refers to a conventional planar PV panel where all of the PV elements are coplanar to each other. As best shown in FIG. 12A, interior reflective surfaces 1232 denote specular reflectors disposed in the interior concave crest extending between two adjacent PV elements 1216a and 1216b, whereas exterior reflective surfaces 1234 denote specular reflectors disposed on exterior convex crests extending between two adjacent PV elements 1216a and 1216b. The reflective surfaces can be provided in the form of substrate on which a metallic film or spray is deposited.

In the illustrated embodiments, the W-module 1214 has first PV elements 1216a and second PV elements 1216b oriented at a non-zero angle, for example about 40°, per PV element relative to a central plane. The interior reflective surfaces 1232 may be disposed on or adjacent to the interior concave crests to redirect incident and albedo light toward active cell surfaces. Optionally, exterior reflective surfaces 1234 may be placed on the exterior convex crests to intercept incident radiation and redirect it into the module interior. Electrical interconnection circuitry may segment cell strings by facet orientation and/or provide bypass elements to reduce series-string bottlenecking under partial shading.

In some embodiments the W-module is fabricated by folding a commercially available flexible PV laminate such that cell rows populate both inward-facing facets. In one implementation, eight cells populate the W-module, whereas a flat module of equal projected area carries six PV elements, thereby increasing active surface area without increasing projected footprint. The angle of the interior concave crest can be about 40°, affording enhanced capture of off-axis radiation. The interior of the W-module may bear reflective surfaces on the interior concave crest to increase irradiance on both surrounding PV elements by redirecting stray and diffuse light. In some other embodiments, reflective surfaces placed on the exterior convex crests act as small concentrators that can intercept incident rays and return them toward shaded interior regions, particularly beneficial at low solar elevation. Materials can include metallic foils, optical films, or dielectric stacks; durability against UV, humidity, particulates, snow, and wind loading is addressed by suitable encapsulation and mechanical fixation.

When all the PV elements are connected in series or long series-parallel chains without segmentation by orientation, partial shading on any one cell, for example on one PV element of the W, constrains current for the entire string, creating a series bottleneck and potential hot-spot risks. This effect is more likely in W-geometries owing to self-shading between PV elements during parts of the day and year. To mitigate these losses, some envisaged embodiments provide electrical separation of facet-specific cell groups, for example, PV elements on one facet in a first string (including the PV elements 1216a) and PV elements on the other facet in a second string (including the PV elements 1216b), optionally with independent maximum power point tracking or diode-isolated combining so that an illuminated facet is not dragged down by a shaded facet. Conventional bypass diodes across sub-strings may be used where appropriate. This approach prevents the shaded side from limiting current on the sunlit side and stabilizes late-day operation.

Two day-long outdoor experiments were conducted in North American climate, with the modules mounted vertically and south-facing to emulate building-integrated use on a wall. The W-module which was tested in shown in FIG. 12B. Measurements were taken every 15 minutes from approximately 09:00 to 16:30 local time, with earlier and later times excluded due to tree shading. The days were clear with low humidity, and irradiance profiles for both days were similar with limited cloud perturbations. Representative W-modules were assembled from market-available flexible panels with USB leads, mounted to a rigid frame; fastening was effected using hook-and-loop strips along the interior concave crests. Electrical measurements used three identical digital multimeters connected at WAGO compact terminals for stable contact. Module temperatures were monitored, and interior reflective surfaces 1232 were present in certain samples as described below.

In one configuration, a W-module with eight cells and interior reflective surfaces was compared to a flat module with six cells sized to have substantially the same projected area. A flat module with eight cells was also used in other comparisons. For equal projected area, the W-module significantly outproduced the six-cell flat module, consistent with the increased active cell area achievable in W-geometry for the same footprint. The reflective surface contribution in this first day could not be fully isolated. In another configuration, a W-module with eight cells and interior reflective surfaces was compared to a W-module with eight cells without reflective surfaces and a flat module with eight cells. Under frontally direct sun, W and flat modules with equal nominal power exhibited similar instantaneous output. In contrast, when the sun moved off axis, the W-geometry maintained higher output, with the W with reflective surface configuration outperforming all others across the day. A late-day “collapse” was observed in some W-runs having reflective surfaces, attributed to inter-facet shading interacting with series-connected strings; separating the facet strings eliminates this behavior. The results are presented in FIG. 12C.

Across mixed insolation angles, results show that W-modules produced about 5%-15% more energy on average than flat modules of equal nominal power, with the advantage most pronounced under oblique insolation. W-modules equipped with interior reflective surfaces 1232 showed the highest energy yield among tested configurations. Gains relative to flat modules were estimated at ~25%-30% on average; when shading-induced electrical losses are addressed by segmented strings and/or bypassing, the net global gain of a W with reflective surfaces configuration is estimated between ~40% and 60%.

The use of reflective surfaces may increase local irradiance on certain cell regions, requiring attention to thermal management and hot-spot avoidance via electrical segmentation and bypass protection. Materials for the reflective surfaces and adhesives are selected for UV, humidity, particulate, snow, and wind exposure over the intended service life. In some embodiments, the exterior reflective surfaces are disposed on the convex crests to reflect incident rays into the module interior before the rays can escape, thereby homogenizing irradiance and improving capture at low solar elevation. The design parameters for the reflective surfaces including, but not limited to, size, curvature, angle, to name a few examples, have been tuned to avoid self-shading and local over-concentration.

The facet angle can be adapted for latitude and target seasonality. Cell counts per facet may be symmetric or asymmetric, and cell types may vary so long as string segmentation preserves facet independence under partial shading. The tested W-module was found to be suitable for building-integrated PV on vertical south-facing walls, where the geometry extends the effective capture window beyond solar noon and leverages albedo and diffuse light. Mounts provide wind-resistant support; fastening can use mechanical clips or adhesives in lieu of temporary hook-and-loop fasteners used during prototyping.

The illustrated W-modules increase active area within the same projected footprint, boost energy yield under off-axis and diffuse conditions, recover otherwise lost flux with interior and/or exterior reflective surfaces, and avoid series bottlenecks and hot-spots caused by inter-facet shading-yielding measured and estimated gains spanning ~5%-15% (W vs. flat) and ~25%-60% (W with reflective surfaces vs. flat), depending on the configuration and electrical mitigation. The disclosed W-modules and methods are applicable to building-integrated PV façades, acoustic/solar barriers, and low-tilt urban installations where vertical placement and oblique or diffuse light are prevalent, enabling higher specific energy yield without increasing the projected panel area.

It is intended that the reflective surfaces which are integrated to the W-shaped geometry PV module can form an enclosure bounded by reflectors. These reflective surfaces thus create a progressive optical trapping effect in which photons bounce between the interior concave reflective surfaces, the exterior convex reflective surfaces (e.g., micro-V ridges), and the semi-transparent lateral PV elements. These reflections can extend the light's path, causing it to make multiple stops that exponentially increase the probability of photon capture to up to 99.2 percent of photons incident on the PV module.

### Example 4—Integration of Luminescent Down-Shifting (LDS) Coatings

This example relates to an LDS coating designed to enhance the efficiency of PV elements described herein. The LDS coating can be provided in the form of an ultra-thin transparent layer, approximately 1 to 3 micrometers thick in some instances. The LDS coating can contain europium-doped phosphorescent powders, which can convert ultraviolet (UV) light, which is typically unusable by silicon solar cells, into visible yellow-green light in the 512-570 nm range, which is ideal for energy conversion. In this example, the LDS coating is applied on the interior reflective surfaces which are installed at the interior concave crests extending between two adjacent PV elements. When sunlight enters the W-shaped geometry either directly or indirectly via one or more reflective surfaces of the solar panel, UV rays strike the LDS-coated interior reflective surfaces. The phosphorescent materials absorb these UV photons and instantly re-emit them as visible photons towards the adjacent PV elements. These converted photons then bounce one or more times between the reflective surfaces of the W-shaped module before being captured by one of the PV elements. Each reflection increases the likelihood of photon absorption, resulting in a conversion and capture rate of up to 99.2% for UV photons.

It was found that this process can significantly boost solar panel performance. Indeed, panels with W-shaped geometry and no LDS coating show a 48.7% improvement over flat panels. However, when the LDS coating is applied, the performance increases by an additional 20-30%, reaching a total gain of 68.7% to 78.7% compared to flat panels. The improvement is due to the LDS coating converting wasted UV energy into usable visible light and the W-shaped geometry amplifying the effect through multiple reflections.

In some embodiments, the LDS coating is made to be durable, with a lifespan exceeding a few years and up to 25 years. Preferably, the LDS coating can resist UV exposure, heat, and/or humidity due to its silicate-based phosphors. The application of the LDS coating can be limited to internal surfaces of the solar panel. The highest priority is given to the internal faces of interior reflective surfaces, which account for approximately 15% of the panel's surface. These reflective surfaces are coated with 99.9% aluminum spray and are essential for maximizing photon reflection and optical trapping. A priority is the internal triangular faces of the micro-V crest structures, which represent about 8% of the panel's surface. These structures help redirect converted light and work synergistically with the concave mirrors. In total, approximately 23% of the panel surface should be coated in some embodiments. Certain areas are preferably excluded from the LDS coating. For instance, the external face of the W-shaped panel, mechanical assembly zones requiring clearance, the surface of the solar cells (for prototype testing), and any mirror or surface directly exposed to rain or snow may not be coated using the LDS coating. Any other flat reflective surfaces can also be coated with LDS, although the efficiency gain is lower due to fewer reflections. The expected improvement is around 5-10%. Coating flat mirrors is recommended only if time and budget allow, with priority given to concave mirrors and micro-V structures for maximum impact. The LDS coating adheres perfectly to the current 99.9% aluminum spray used on the mirrors. No changes to the mirror material are necessary, and the rough surface of the aluminum spray even enhances adhesion compared to smooth glass.

The LDS coating can be phosphorus-based in some embodiments. Examples of such phosphorus-based material can include, but are not limited to, Strontium Aluminate Europium Dysprosium Doped Phosphor (SrAl₂O₄:Eu,Dy), to name only one example. An exemplary formulation of the Luminescent Down-Shifting (LDS) phosphor coating comprises a sol-gel matrix embedding two types of phosphors for ultraviolet-to-visible light conversion, along with solvents, catalysts, and adhesion promoters to ensure optimal dispersion, stability, and adherence to aluminum mirror surfaces. The primary active components include 6 grams of SrAl₂O₄:Eu,Dy phosphorus, which can convert ultraviolet light into green visible light at approximately 512 nm. Optionally, YAG: Ce phosphor may be added to extend the emission spectrum toward yellow light (~550 nm). The sol-gel binder matrix is formed using tetraethyl orthosilicate (TEOS), which acts as the silicate precursor. To facilitate hydrolysis and condensation of the sol-gel, ethanol is used as the solvent, and deionized water is added to initiate hydrolysis. The water may be substituted with distilled water if necessary. A catalytic amount of hydrochloric acid (HCl) is added to accelerate the hydrolysis reaction. Diluted muriatic acid (10×) may be used as a source. To ensure uniform dispersion of the phosphor powders within the sol-gel matrix, Triton X-100 surfactant can be incorporated. For improved adhesion of the LDS coating to aluminum mirror surfaces, GPTMS (3-Glycidyloxypropyltrimethoxysilane) can be added as an adhesion promoter. Such a recipe can yield a stable, transparent coating capable of converting UV light into visible light within the optimal absorption range of silicon solar cells. The coating adheres effectively to rough aluminum spray surfaces and is designed for long-term durability under UV exposure, heat, and humidity. Other similar recipe, where the same ingredients can have differing quantities or concentrations, and/or different ingredients, can be used in some other embodiments.

### Example 5—Amplifying Structure for PV Elements

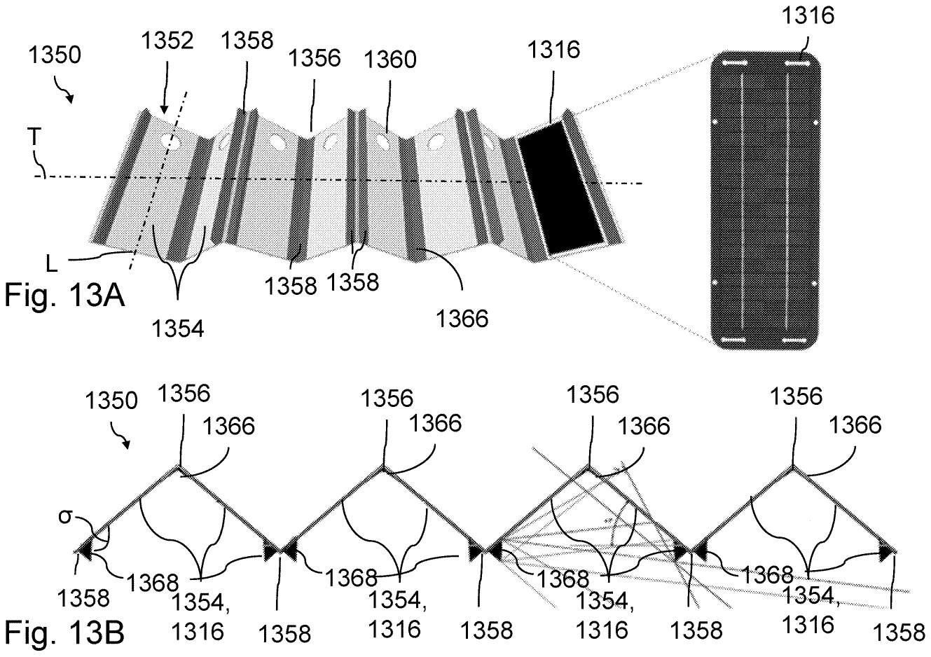

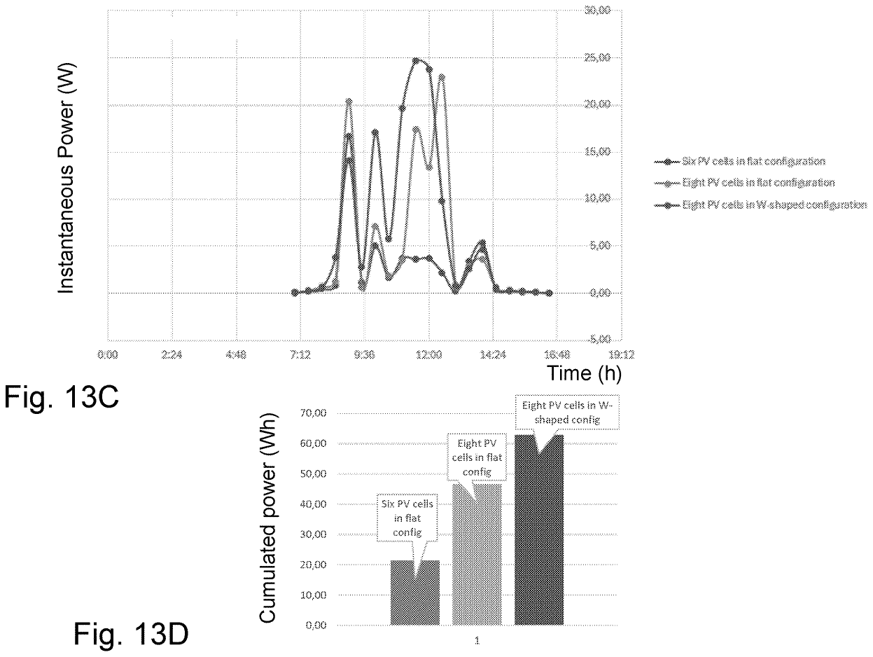

FIG. 13A shows an example of an amplifying structure 1350 for a plurality of PV elements 1316. As depicted, the amplifying structure 1350 has a frame 1352. The frame 1352 has wall portions 1354 each having a length extending along a longitudinal orientation L. The wall portions 1354 are spaced relative to one another along a transverse orientation T which is generally normal to the longitudinal orientation L. As illustrated, the wall portions 1354 are inclined about a corresponding length thereof. As such, transverse widths of the wall portions 1354 form alternating positive and negative non-null angles relative to the transverse orientation T. In a manner analogous to the embodiments described in detail above. The wall portions 1354 form a non-planar surface profile which has a W-shape in this embodiment. Such a shape forms a series of concave crests 1356 interspersed with a series of convex crests 1358. As depicted, the crests 1356 and 1358 extend along the longitudinal orientation L between the wall portions 1354. The wall portions 1354 are configured to receiving a corresponding number of PV elements 1316 therealong, an example of which being shown on the rightmost one of the wall portions 1354. The wall portions 1354 can have an access recess 1360 through which electrical components can pass. For instance, the access recess 1360 can be used to connect the junction box of the PV elements 1316 to an external electrical circuit. In this example, the amplifying structure 1350 has a series of eight wall portions 1354. However, in some other embodiments, the amplifying structure 1350 can have fewer than weight wall portions, or more than eight wall portions. The number of wall portions 1354 can depend on many parameters including, but not limited to, the desired footprint of the resulting PV panel.

As best shown in FIG. 13B, the amplifying structure 1350 can be provided with reflective surfaces positioned along the concave crests 1358 and/or the convex crests 1356. The reflective surfaces can be omitted in some other embodiments, as they are only optional. As such, the reflective surfaces are adapted to reflect incident light towards the PV elements 1316 when receiving on the corresponding wall portions 1354. Indeed, in this example, the reflective surfaces include a series of first reflective surfaces 1366 which extend along the concave crests 1356. The first reflective surfaces 1366 have a concave shape disposed within the concave crests 1356 in the illustrated embodiment. The concave shape of the first reflective surfaces 1366 is curved to snugly fit, more or less, in the corner formed by the concave crests 1356.

Additionally or alternately, the reflective surfaces include second reflective surfaces 1368 which extend along the convex crests 1358. As shown, the second reflective surfaces 1368 are provided in the form of a reflective facet adjacent a corresponding one of the wall portions 1354 and which form an angle σ relative to the one of the wall portions 1354. The angle σ is determined to enhance reflection of the incident light towards one or more of the wall portions 1354. In the illustrated example, the reflective facet can form an obtuse angle σ relative to the corresponding wall portion. The obtuse angle σ can range between 90 and 150 degrees, depending on the embodiment. In this example, each wall portion 1354 has a corresponding reflective facet 1358 positioned along a side of the convex crests. In this manner, incident light can be captured and reflected towards one or more of the wall portions 1354 to enhance electricity production. The performances of such an embodiment are presented in detail in FIGS. 13C and 13D.

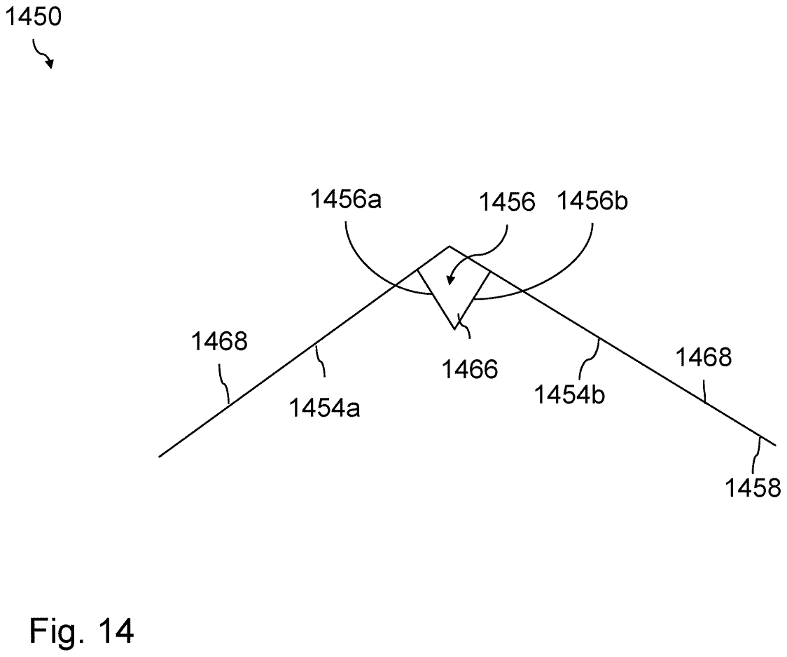

FIG. 14 shows another example of the amplifying structure 1450. As depicted, the first reflective surfaces 1466 have a different design. Indeed, in this example, the first reflective surfaces 1466 each have a convex shape which protrudes from a corresponding one of the concave crests 1456. More specifically, the convex shape forms a V-shape which protrudes from the corresponding one of the concave crests 1456. The V-shape has a first reflective facet 1456a adjacent a first wall portion 1454a and a second reflective facet 1456b adjacent a second wall portion 1454b. In this way, the first reflective facet 1456a can reflect incident light towards the first wall portion 1454a and the second reflective facet 1456b can reflect the incident light towards the second wall portion 1454b. It was simulated that with such a V-shape, sunlight could be more optimally reflected towards the surrounding PV elements, thereby increasing the production of electricity for a given sun exposure.

It is understood that any one of the amplifying structures described herein can be assembled into a PV panel assembly using a plurality of PV elements. The amplifying structure and the PV elements can be provided in the form of a kit of parts including instructions to assembly the PV elements onto the wall portions of the amplifying structure to form a corresponding PV panel assembly.

The inventor has found that the principles described above with reference to the illustrated PV panels, PV panel assembly and amplifying structure is part of a reflectricity phenomenon. The reflectricity term has been coined to encompass any physical principle directed to the amplification of photonic capture through the use of three-dimensional macroscale geometries (having characteristic dimensions between approximately 1 cm and 10 m or more) that incorporate inclined photovoltaic surfaces in combination with strategically positioned reflective surfaces. These configurations generate multiple optical reflections in accordance with the laws of geometric optics, thereby extending the effective optical path length of incident photons, increasing the probability of photon absorption, and producing a non-Lambertian angular capture behavior. The reflectricity principle is meant to encompass any three-dimensional macroscale geometries including, but not limited to, the W-shape geometry, zig-zag structures having various angular orientations, horizontal versus vertical accordion-type arrangements, inverted pyramidal geometries, interlocking hexagonal structures, dome-shaped architectures, parabolic configurations, cylindrical arrangements, and similar variations of the inclined wall portions described herein.

As can be understood, the examples described above and illustrated are intended to be exemplary only. For example, although the examples described above relate to building-integrated/integratable PV panels, it is understood that the present disclosure is meant to encompass any PV panel incorporating PV elements disposed in the W-shaped three-dimensional structure. Although the PV panel described above exhibits different variations of the alternatingly angled PV elements, it is intended that, in some other embodiments, the alternatingly angled feature of the PV elements can be omitted. Indeed, in accordance with another aspect, there is described a PV panel having a reflective chamber having one or more reflective surfaces and inside which a plurality of PV elements are mounted. In some instances, the reflective chamber is provided in the form of an open chamber having an opening through which incoming sunlight can shine unopposed. In these embodiments, the combination of the PV elements mounted inside the reflective chamber, and exposed to the opening, together with the presence of the one or more reflective surfaces ensure that light entering the reflective chamber bounces within the reflective chamber via the one or more reflective surfaces. As explained above, these repeated exposition to the sunlight via the reflective surfaces can increase considerably. In these embodiments, one or more Fresnel lenses may be mounted proximate the opening of the reflective chamber to redirect more light thereinside. An example application for which the PV panel and system can be useful can include, but is not limited to, solar desalination, and the like. The scope is indicated by the appended claims.

What is claimed is:

1. A photovoltaic (PV) panel system comprising:
a frame;
a plurality of PV elements mounted to the frame, the plurality of PV elements having a length extending along a longitudinal orientation, the plurality of PV elements spaced relative to one another along a transverse orientation generally normal to the longitudinal orientation, the plurality of PV elements inclined about a corresponding length thereof, transverse widths of the plurality of PV elements forming alternating positive and negative non-null angles relative to the transverse orientation, the plurality of PV elements including a first set of PV elements facing a first orientation, and a second set of PV elements facing a second orientation different from the first orientation;
an electricity management module having:
a first electricity management device electrically connected to the first set of PV elements; and
a second electricity management device electrically connected to the second set of PV elements and independent from the first set of PV elements;
wherein the first electricity management device and the second electricity management device each draws electricity generated by the first set of PV elements and the second set of PV elements, respectively.

2. The PV panel system of claim 1 wherein the PV elements of the first set are connected to one another in series, the PV elements of the second set being connected to one another in series.

3. The PV panel system of claim 1 wherein the PV elements are connected to the electricity management module using dedicated conductors.

4. The PV panel system of claim 3 wherein the frame has a plurality of wall portions each receiving a corresponding PV element, the wall portions having an access recess through which the dedicated conductors pass.

5. The PV panel system of claim 1 wherein the electricity management module has at least a third electricity management device independent from the first electricity management device and the second electricity management device, the third electricity management device electrically connected to a given set of the PV elements.

6. The PV panel system of claim 1 wherein the electricity management module is configured for activating or deactivating either one or both the first electricity management device and the second electricity management device based on one or more instantaneous sensor readings.

7. The PV panel system of claim 1 wherein the PV elements form a non-planar surface profile having a transverse cross-section defining a W-shape.

8. The PV panel system of claim 1 wherein proximate longitudinal edges of any two adjacent ones of the plurality of PV elements are abutted to one another, abutting ones of the plurality of PV elements forming a succession of concave crests and convex crests each extending along the longitudinal orientation.

9. The PV panel system of claim 8 further comprising first reflective surfaces disposed along at least some of the concave crests.

10. The PV panel system of claim 9 wherein the first reflective surfaces have a concave shape snugly received along the at least some of the concave crests.

11. The PV panel system of claim 9 wherein the first reflective surfaces have a convex shape protruding from corresponding ones of the at least some of the concave crests.

12. The PV panel system of claim 8 further comprising second reflective surfaces disposed along at least some of the convex crests.

13. The PV panel system of claim 12 wherein the second reflective surfaces protrude inwardly from corresponding ones of the convex crests.

14. The PV panel system of claim 1 wherein the positive non-null angles range between 30 and 50 degrees, and the negative non-null angles range between −30 and −50 degrees.

15. The PV panel system of claim 1 wherein the PV elements are flat PV elements.

16. The PV panel system of claim 1 wherein the PV elements have a coating incorporating one or more quantum dots.

17. The PV panel system of claim 1 wherein the PV panel system is non-Lambertian.

18. A method of managing electricity in a photovoltaic (PV) panel system comprising:
using a first electricity management device electrically connected to a first set of PV elements, the PV elements of the first set facing a first orientation, and a second electricity management device electrically connected to a second set of PV elements, the PV elements of the second set facing a second orientation different from the first orientation, drawing electricity from the first set of PV elements independently from drawing electricity from the second set of PV elements.
